(19) United States
(12) Patent Application Publication
(10) Pub. No.: US 2023/0080970 A1
(43) Pub. Date: Mar. 16, 2023

(54) SUBSTRATE PROCESSING APPARATUS

(71) Applicant: ASM IP Holding B.V., Almere (NL)

(72) Inventors: YongJin Jeong, Osan-si (KR); Juill Lee, Cheonan-si (KR); DaeYoun Kim, Seo-gu (KR); HeeBum Chae, Hwaseong-si (KR)

(21) Appl. No.: 17/942,277

(22) Filed: Sep. 12, 2022

Related U.S. Application Data
(60) Provisional application No. 63/244,546, filed on Sep. 15, 2021.

(51) Int. Cl. H01L 21/68; H01L 21/67; H01L 21/687

(52) U.S. Cl. CPC H01L 21/68; H01L 21/6875; H01L 21/67115; H01L 21/68785

(57) ABSTRACT

A substrate processing apparatus capable of solving a misalignment problem of chamber portions due to thermal deformation or a vacuum force during high-temperature processing includes a first plate; a second plate on the first plate; a position control unit configured to change a relative position of the second plate with respect to the first plate; and a support unit configured to permit movement of the second plate while supporting the second plate.

### CROSS REFERENCE TO RELATED APPLICATIONS

This application claims priority to U.S. Provisional Pat. Application Serial No. 63/244,546, filed Sep. 15, 2021, and titled SUBSTRATE PROCESSING APPARATUS, the disclosure of which is hereby incorporated by reference in its entirety.

### BACKGROUND

### 1. Field

One or more embodiments relate to a substrate mounting unit and a substrate processing apparatus including the same, and more particularly, to a substrate mounting unit for preventing deterioration of process uniformity due to sagging or deformation of a chamber at a high temperature, and a substrate processing apparatus including the substrate mounting unit.

### 2. Description of the Related Art

A substrate processing apparatus for processing a semiconductor or display substrate, such as a chemical vapor deposition (CVD) reactor or an atomic layer deposition (ALD) reactor, includes a gas supply unit, a substrate support unit, an exhaust unit, and other accessory components. In order to maintain smooth substrate handling and stable process results, the components need to be properly placed in designated locations within the reactor. However, in a high-temperature process, the components may be dislocated from the designated locations within the reactor or may be out of alignment with each other due to thermal expansion or vacuum force applied to the reactor or components constituting the reactor. In this case, a stable substrate process is difficult.

For example, thermal deformation of a reactor lid including a gas supply unit may cause a distance between the gas supply unit and an oppositely arranged substrate support unit to become inconsistent with location, thereby reducing the uniformity of a thin film deposited on a substrate. In addition, exhaust flow of gas within a reaction space becomes non-uniform due to thermal deformation at high temperatures and due to a mismatch in the center of symmetry between the substrate support unit and the reactor components surrounding the substrate support unit.

In addition, in contrast to the environment (i.e., room temperature and atmospheric pressure) in which the initial installation and maintenance of the substrate processing apparatus takes place, in the case of high temperature and vacuum conditions under which substrate processing is performed, misalignment of the substrate support unit occurs due to thermal deformation or vacuum force applied to the substrate processing apparatus. Accordingly, there is a problem in that the symmetry of arrangement with respect to the components in the reactor is lost.

### SUMMARY

One or more embodiments include maintaining a constant gap between a gas supply unit and a substrate mounting unit arranged opposite thereto, that is, a reaction space, under a high temperature and/or vacuum environment.

One or more embodiments include maintaining a constant gap between a substrate mounting unit and a gas flow control unit surrounding the substrate mounting unit under a high temperature and/or vacuum environment.

One or more embodiments include adjusting and correcting a position of a substrate mounting unit under a substrate processing temperature without lowering the temperature of a substrate processing apparatus.

Additional aspects will be set forth in part in the description which follows and, in part, will be apparent from the description, or may be learned by practice of the presented embodiments of the disclosure.

According to one or more embodiments, a substrate processing apparatus includes: a first plate; a second plate on the first plate; a position control unit configured to change a relative position of the second plate with respect to the first plate; and a support unit configured to permit movement of the second plate while supporting the second plate.

According to an example of the substrate processing apparatus, the support unit may be configured to prevent an over-constraint state of the second plate by the position control unit.

According to another example of the substrate processing apparatus, the support unit may include an elastic member configured to generate an elastic force that changes according to the movement of the second plate.

According to another example of the substrate processing apparatus, the substrate processing apparatus may include a substrate mounting unit connected to the second plate; and a driving unit connected to the first plate, wherein a first moving range of the substrate mounting unit moved by the driving unit may be greater than a second moving range of the substrate mounting unit moved by the position control unit.

According to another example of the substrate processing apparatus, the position control unit may include a vertical position control unit configured to vertically move the second plate with respect to the first plate.

According to another example of the substrate processing apparatus, the substrate processing apparatus may further include a bracket connected to the first plate, wherein the vertical position control unit may be fixed to the bracket and configured to apply a force toward an upper surface of the second plate.

According to another example of the substrate processing apparatus, the support unit may be below the vertical position control unit.

According to another example of the substrate processing apparatus, the substrate processing apparatus may further include a lower cover connected to the first plate, wherein the support unit may extend from the lower cover toward the second plate through a through hole of the first plate, and a side surface of the support unit may be apart from a side surface of the through hole.

According to another example of the substrate processing apparatus, the support unit may extend through at least a portion of the second plate, and the side surface of the support unit may be apart from a side surface of the second plate.

According to another example of the substrate processing apparatus, the substrate processing apparatus may further include a substrate mounting unit connected to the second plate, and the position control unit may further include a horizontal position control unit configured to horizontally move the second plate with respect to the first plate, wherein the horizontal position control unit may be configured to perform a compensating operation for horizontal movement of the substrate mounting unit caused by tilting of the second plate by the movement of the vertical position control unit.

According to another example of the substrate processing apparatus, a length from the center of the second plate to a contact point between the second plate and the vertical position control unit may be a first length, a length from the second plate to the substrate mounting unit may be a second length, and the vertical position control unit may move by a third length at the contact point, wherein the horizontal position control unit may be configured to move the second plate by a value obtained by multiplying the second length by the third length and dividing the first length.

According to another example of the substrate processing apparatus, the position control unit may include a horizontal position control unit configured to horizontally move the second plate with respect to the first plate.

According to another example of the substrate processing apparatus, the support unit may be arranged on a side surface of the second plate.

According to another example of the substrate processing apparatus, the substrate processing apparatus may further include a first bracket connected to the first plate, wherein the vertical position control unit may be fixed to the first bracket and configured to apply a force toward a side surface of the second plate.

According to another example of the substrate processing apparatus, the support unit may include an elastic member and an elastic force transmission unit connected to the elastic member, wherein the elastic force transmission unit may be configured to apply an elastic force generated by the elastic member to the side surface of the second plate.

According to another example of the substrate processing apparatus, the substrate processing apparatus may further include a second bracket connected to the first plate, wherein the elastic member and the elastic force transmission unit may be inserted into an accommodating portion of the second bracket, and the elastic force transmission unit may protrude from the side surface of the second bracket through the receiving part of the second bracket and contact a side surface of the second plate.

According to another example of the substrate processing apparatus, the elastic force transmission unit may have a round end, and the end of the elastic force transmission unit and an end of the horizontal position control unit may be configured to contact the side surface of the second plate at the same level.

According to another example of the substrate processing apparatus, the elastic force transmission unit may include: a body portion inserted into the elastic member; a round portion connected to the body portion; and an extension protruding from the body portion, wherein the extension may be in contact with the elastic member.

According to another example of the substrate processing apparatus, the horizontal position control unit may include two position control units arranged on a side surface of the second plate, wherein the two position control units and the support unit may be symmetrically arranged with respect to the center of the second plate, and as the two position control units move toward the center of the first plate by a first distance, the second plate may move toward the support unit by a second distance, wherein the second distance may be twice the first distance.

According to another example of the substrate processing apparatus, the second plate may include a first protrusion, a second protrusion, and a third protrusion, the position control unit may include a first position control unit on the first protrusion, a second position control unit on the second protrusion, a third position control unit on the third protrusion, a fourth position control unit next to the first protrusion, and a fifth position control unit next to the second protrusion, and the support unit may include a first support unit next to the third protrusion, a second support unit below the first position control unit, a third support unit below the second position control unit, and a fourth support unit below the third position control unit.

According to one or more embodiments, a substrate processing apparatus includes: a first plate including a first bracket, a second bracket, and a third bracket; a second plate arranged on the first plate and including a first protrusion, a second protrusion, and a third protrusion; a first position control unit arranged between the first bracket and an upper surface of the first protrusion; a second position control unit arranged between the second bracket and an upper surface of the second protrusion; a third position control unit arranged between the third bracket and an upper surface of the third protrusion; a fourth position control unit arranged between the first bracket and a side surface of the first protrusion; a fifth position control unit arranged between the second bracket and a side surface of the second protrusion; a first support unit arranged between the third bracket and a side surface of the third protrusion; a second support unit below the first position control unit; a third support unit arranged below the second position control unit; and a fourth support unit below the third position control unit.

According to one or more embodiments, a substrate processing apparatus includes: a first plate; a second plate on the first plate; a position control unit configured to move the second plate with respect to the first plate; and a support unit configured to provide an elastic force to receive the movement of the second plate by the position control unit.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view of a substrate processing apparatus according to embodiments;

FIGS. 2 to 4 are views of a substrate processing apparatus according to other embodiments;

FIG. 5 is a view of a substrate processing apparatus according to other embodiments;

FIGS. 6 to 9 are views of a substrate processing apparatus according to other embodiments;

FIG. 10 is a view of a substrate processing apparatus according to other embodiments;

FIGS. 11A and 11B are views illustrating passive movement of a support unit in response to active movement of a position control unit;

FIG. 12 is a flowchart illustrating a substrate processing method according to other embodiments;

FIGS. 13 to 14 are views of a substrate processing apparatus according to other embodiments;

FIG. 15 is a view of a substrate processing apparatus according to the disclosure;

FIGS. 16A-16C are views illustrating an embodiment of a substrate support unit and a heating block support unit according to the disclosure;

FIG. 17 is a view illustrating a movable direction and a tilting direction of a heating block by the heating block support unit of FIG. 16;

FIGS. 18A and 18B are cross-sectional views of a moving plate control unit;

FIG. 19 is a view illustrating an embodiment of a position control unit;

FIGS. 20A and 20B are views illustrating the principle of horizontal movement of a moving plate according to an embodiment;

FIG. 21 is a view illustrating a horizontal moving direction of a moving plate and a heating block according to a movement distance and a moving direction of a horizontal movement position control unit of a substrate support unit corresponding to each reactor, in a substrate processing apparatus in which a plurality of reactors are installed;

FIG. 22 is a view of a multi-reactor in which the symmetry of arrangement between a heating block and a chamber structure surrounding the heating block is reduced due to thermal deformation at a high temperature;

FIG. 23 is a view illustrating an embodiment of tilting a moving plate;

FIG. 24 is a view illustrating compensation movement in a horizontal direction performed after tilting the moving plate of FIG. 23;

FIG. 25 is a view illustrating a movement state of each of horizontal position control units for compensating for moving a heating block in a horizontal direction when the heating block is tilted by moving each of vertical position control units by a certain distance; and

FIG. 26 is a flowchart illustrating a process of tilt and horizontal compensation movement of the heating block according to FIG. 25.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Reference will now be made in detail to embodiments, examples of which are shown in the accompanying drawings, wherein like reference numbers refer to like elements throughout. In this regard, the present embodiment may have different forms and should not be construed as being limited to the description described herein. Accordingly, embodiments are only described below with reference to the drawings to illustrate aspects of the present description. As used herein, the term “and/or” includes any and all combinations of one or more associated listed items. When an expression such as “at least one” precedes a list of elements, the entire list of elements is modified, not individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

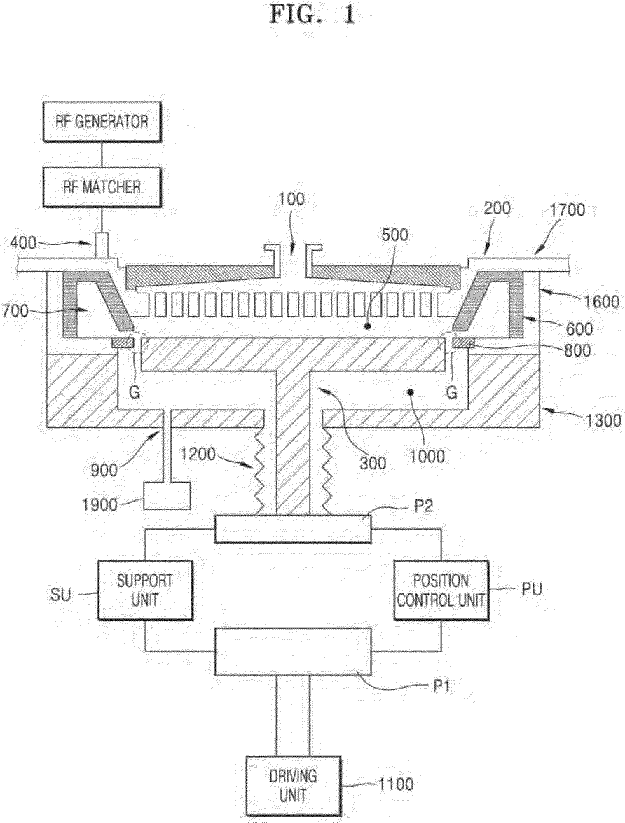

FIG. 1 is a view of a substrate processing apparatus according to embodiments.

Referring to FIG. 1, a reactor in the substrate processing apparatus may include an upper body 1600 and a lower body 1300. The upper body 1600 and the lower body 1300 may be connected to each other. In more detail, the upper body 1600 and the lower body 1300 of a reactor may form inner spaces 500 and 1000 while face-contacting and face-sealing each other. The reactor may include, in the inner spaces 500 and 1000, a substrate mounting unit 300, and a ring 800 surrounding the substrate mounting unit 300 and arranged between the substrate mounting unit 300 and the upper body 1600.

The reactor may be configured to perform processing on an object to be processed, such as a substrate. For example, the reactor may be configured to perform heating, deposition, etching, polishing, ion implantation, and/or other processing on the object to be processed. In some embodiments, the reactor may be configured to perform a movement function, a vacuum sealing function, a heating function, an exhaust function, and/or other functions for the object to be processed such that the object is processed in the reactor. In an optional embodiment, the reactor may be a reactor in which an atomic layer deposition (ALD) or a chemical vapor deposition (CVD) process is performed.

The upper body 1600 of the reactor may include a first gas inlet 100, a gas supply unit 200, an exhaust unit 600, and the ring 800. The lower body 1300 of the reactor may include a second gas inlet 900. The upper body 1600 and the substrate mounting unit 300 may form the reaction space 500. The lower body 1300 and the substrate mounting unit 300 may form the lower space 1000. A second gas generator 1900 may generate a filling gas, and the filling gas may be transmitted to the lower space 1000 through the second gas inlet 900.

The ring 800 may surround the substrate mounting unit 300 and may be arranged between the substrate mounting unit 300 and the upper body 1600. The ring 800 may generally have a circular ring shape, but is not limited thereto. For example, when the substrate mounting unit 300 has a quadrangular shape, the ring 800 may have a quadrangular ring shape. The ring 800 may be fixed to the upper body 1600. In an optional embodiment, the ring 800 may be movably installed on the upper body 1600.

A gap G may be between the ring 800 and the substrate mounting unit 300. The reaction space 500 and the lower space 1000 may communicate with each other through the gap G. In this case, a filling gas may be introduced into the lower space 1000 through the second gas inlet 900. This filling gas forms a gas curtain in the gap G between the substrate mounting unit 300 and the ring 800 to prevent gas in the reaction space 500 from flowing into the lower space 1000.

In some embodiments, the filling gas may be nitrogen or argon. Alternatively, gas having a lower discharge rate than the gas supplied to the reaction space 500 may be supplied to the lower space 1000 through the second gas inlet 900 in order to prevent parasitic plasma from being generated in the lower space 1000 when the plasma is generated in the reaction space 500.

The ring 800 may be between the upper body 1600 and the substrate mounting unit 300. For example, the ring 800 may be a gas flow control ring (FCR). The ring 800 may control pressure balance between the reaction space 500 and the lower space 1000 by adjusting a width of the gap G between the upper body 1600 and the substrate mounting unit 300.

In more detail, the ring 800 adjusts a width of the gap G between the upper body 1600 and the substrate mounting unit 300, that is, a width of the gap between the ring 800 and the substrate mounting unit 300. Thus, the ring 800 may control a flow rate of a filling gas and a process gas around the gap G, thereby controlling the pressure of the filling gas and process gas.

The substrate mounting unit 300 may include a susceptor body for supporting the substrate and a heater for heating the substrate supported by the susceptor body. For loading/unloading of the substrate, the substrate mounting unit 300 may be configured to be vertically movable by being connected to a driving unit 1100.

The substrate processing apparatus may include a first plate P1 and a second plate P2 arranged between the substrate mounting unit 300 and the driving unit 1100. The first plate P1 may be connected to the driving unit 1100. The second plate P2 may be on the first plate P1, and the first plate P1 and the second plate P2 may be connected to each other through a support unit SU.

The first plate P1, the second plate P2, and the substrate mounting unit 300 may move by the driving of the driving unit 1100. In more detail, a driving force generated by the driving unit 1100 may be transmitted to the first plate P1, and the transmitted driving force may be transmitted from the first plate P1 to the second plate P2 through the support unit SU. As a result, the substrate mounting unit 300 connected to the second plate P2 may also be moved by the driving of the driving unit 1100.

The substrate processing apparatus may further include a position control unit PU and the support unit SU. The position control unit PU may be configured to change a relative position of the second plate P2 with respect to the first plate P1 to maintain a constant interval of the reaction space 500 or to maintain a constant interval of the gap G between the substrate mounting unit 300 and the ring 800.

The driving unit 1100 may be configured to elevate the substrate mounting unit 300 to load/unload the substrate onto the substrate mounting unit 300. However, the position control unit PU may be configured to tilt and/or horizontally move the substrate mounting unit 300 for fine adjustment of the position of the substrate mounting unit 300. In addition, the driving unit 1100 may simultaneously move the first plate P1 and the second plate P2, while the position control unit PU may move only the second plate P2 without moving the first plate P1.

The driving unit 1100 and the position control unit PU may have movement ranges of different scales. The driving unit 1100 may have a movement range of, for example, several tens of cm, while the position control unit PU may have a movement range of several millimeters. In other words, a first movement range of the substrate mounting unit 300 moved by the driving unit 1100 may be greater than a second movement range of the substrate mounting unit 300 moved by the position control unit PU.

The support unit SU may be configured to support the second plate P2. In more detail, a static support function and a dynamic support function for the support unit SU may be performed. First, with respect to the static support function, the support unit SU may be configured to provide a fixing force for fixing the second plate P2 so that the substrate mounting unit 300 may be maintained at a certain intended position. In other words, the support unit SU may perform a function of supporting the second plate P2 so that the second plate P2 may maintain a static state.

With respect to the dynamic support function, when the second plate P2 is moved by the position control unit PU, the support unit SU may allow the second plate P2 to move. The support unit SU may provide a support force for the second plate P2 while allowing the movement of the second plate P2. In other words, the support unit SU may support the second plate P2 with respect to relative movement of the second plate P2 with respect to the first plate P1, and the support unit SU may support the second plate P2 in a dynamic state of the second plate P2.

The support unit SU may be configured to transmit a fixing force of the first plate P1 with respect to the second plate P2 connected to the substrate mounting unit 300. In other words, the support unit SU may connect the first plate P1 to the second plate P2 such that a driving force generated by the driving unit 1100 may be transmitted from the first plate P1 to the second plate P2. A bolt or the like may be used for such a connection mechanism, but it should be noted that the transfer of a fixing force by the bolt or the like makes the second plate P2 over-constrained (i.e., a state that does not allow the movement of the second plate P2), thereby limiting relative movement between the first plate P1 and the second plate P2.

On the other hand, according to embodiments, the support unit SU may prevent the second plate P2 from being over-constrained by the position control unit PU. As described above, when the driving unit 1100 and the substrate mounting unit 300 are mechanically fixed using a bolt or the like, fine adjustment of the substrate mounting unit 300 is impossible due to an over-constrained state. On the other hand, because the support unit SU according to embodiments is configured to prevent such an over-constrained state, fine adjustment of the substrate mounting unit 300 may be achieved.

A stretchable portion 1200 may be between a lower surface of the lower body 1300 and the second plate P2. The stretchable portion 1200 may be arranged between the lower surface of the lower body 1300 and the second plate P2 to isolate the lower space 1000 from the outside.

The stretchable portion 1200 may be stretched and contracted according to movement of the substrate mounting unit 300 and the second plate P2. For example, the stretchable portion 1200 may have a corrugated configuration (e.g., a bellows). When the first plate P1, the second plate P2, and the substrate mounting unit 300 are raised by the driving unit 1100, the stretchable portion 1200 may contract. When the first plate P1, the second plate P2, and the substrate mounting unit 300 are descended by the driving unit 1100, the stretchable portion 1200 may expand.

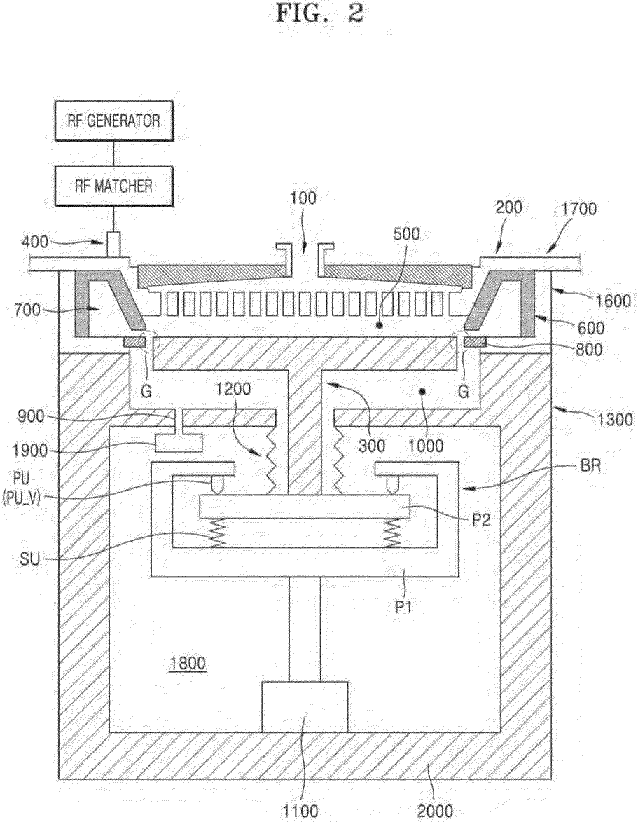

In an optional embodiment, the stretchable portion 1200 may be configured to have elasticity. For example, the elasticity of the stretchable portion 1200 may be adjusted to be stretched or contracted in response to vertical movement of the substrate mounting unit 300 so that shielding between the lower surface of the lower body 1300 and the second plate P2 may be maintained. Due to the shielding of the stretchable portion 1200, the reaction space 500 and the lower space 1000 (of FIG. 2) may be separated from a chamber space 1800 (of FIG. 2).

A process gas introduced through the first gas inlet 100 may be supplied to the reaction space 500 and the substrate through the gas supply unit 200. The gas supply unit 200 may be a showerhead, and a base of the showerhead may include a plurality of gas supply holes formed to eject the process gas (e.g., in a vertical direction). A process gas supplied on the substrate may undergo a chemical reaction with the substrate or a chemical reaction between gases, and then deposit a thin film or etch a thin film on the substrate.

In a plasma process, radio frequency (RF) power may be electrically connected to the gas supply unit 200 functioning as one electrode. In more detail, an RF rod 400 connected to RF power may be connected to the gas supply unit 200. In this case, upper RF power may be supplied to the gas supply unit 200 through an RF generator, an RF matcher, and the RF rod 400, and a reaction gas introduced into the reaction space 500 through the first gas inlet 100 may be activated to generate plasma.

In the reaction space 500, a residual gas or un-reacted gas remaining after the chemical reaction with the substrate may be exhausted to the outside through an exhaust space 700 in an exhaust duct 600 and an exhaust pump (not shown). An exhaust method may be upper exhaust or lower exhaust.

FIGS. 2 to 4 are views of a substrate processing apparatus according to other embodiments. The substrate processing apparatus according to the embodiments may be a variation of the substrate processing apparatus according to the above-described embodiments. Hereinafter, repeated descriptions of the embodiments will not be given herein.

Referring to FIGS. 2 to 4, the first plate P1, the second plate P2, the position control unit PU, and the support unit SU of the substrate processing apparatus are shown in more detail. As described above, the driving unit 1100 is connected to the first plate P1, and the substrate mounting unit 300 is connected to the second plate P2. The position control unit PU and the support unit SU may be between the first plate P1 and the second plate P2.

The position control unit PU may include a fixed body fixed to the first plate P1 and a moving body configured to move to change a length of the position control unit PU. In some embodiments, the moving body may include a round end, and the end may contact the substrate mounting unit 300 to form a contact point.

The support unit SU may include an elastic member. The elastic member may be configured to generate an elastic force that changes according to movement of the second plate P2. The elastic force of the elastic member may be selected as an appropriate value to accommodate the movement of the second plate P2 by the position control unit PU. In other words, the elastic force of the elastic member may be selected to be a value that allows the second plate P2 to be fixed at an intended position while preventing over-constraint of the second plate P2.

Referring to FIG. 2, the position control unit PU of the substrate processing apparatus may include a vertical position control unit PU_V. The vertical position control unit PU_V may be configured to vertically move the second plate P2 with respect to the first plate P1. A fixed body of the vertical position control unit PU_V may be connected to the first plate P1, and a moving body of the vertical position control unit PU_V may contact an upper surface of the second plate P2.

In an optional embodiment, the substrate processing apparatus may further include a bracket BR connected to the first plate P1. The bracket BR may be configured separately from the first plate P1 or may be integrally formed with the first plate P1. The vertical position control unit PU_V may be fixed to the bracket BR. The vertical position control unit PU_V fixed to the first plate P1 through the bracket BR may apply a force toward the upper surface of the second plate P2, and by the force, the second plate P2 may be tilted or moved in the vertical direction.

The support unit SU may be below the vertical position control unit PU_V. In some embodiments, the vertical position control unit PU_V and the support unit SU may be symmetrically arranged with respect to the second plate P2. Accordingly, the support unit SU may generate a support force (e.g., an elastic force) corresponding to a force applied toward the upper surface of the second plate P2 generated by the vertical position control unit PU_V.

When tilting of the gas supply unit 200 occurs in a high-temperature vacuum process, the vertical position control unit PU_V may be used to tilt the substrate mounting unit 300 to correspond to such tilting. For example, when the vertical position control unit PU_V on the left side with reference to FIG. 2 maintains the existing position and controls the vertical position control unit PU_V on the right side to increase a length of the vertical position control unit PU_V on the right side, the second plate P2 and the substrate mounting unit 300 connected to the second plate P2 may be tilted in a clockwise direction. Through this tilting, the reaction space 500 having a constant interval may be achieved.

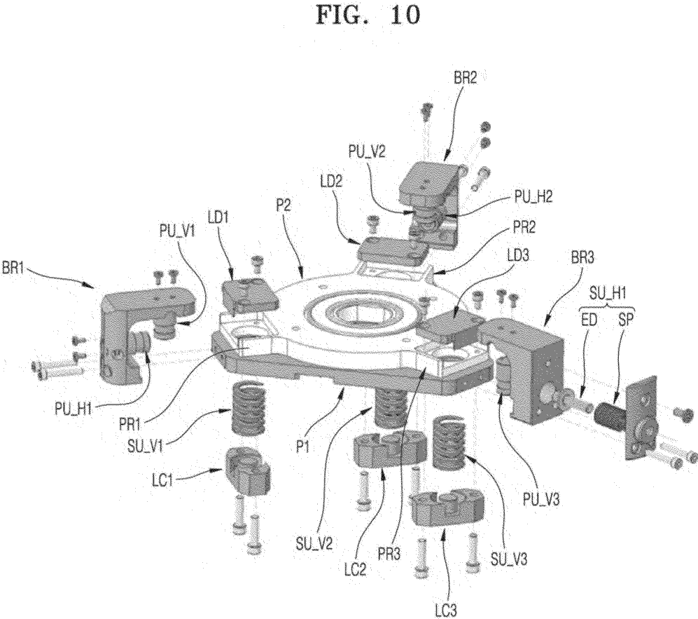

Although the drawing shows that a plurality of vertical position control units are arranged, they may be singular. In some embodiments, there may be two vertical position control units as shown in FIG. 2 or three as shown in FIG. 10, and although not shown in the drawings, four or more vertical position control units may be arranged. The plurality of vertical position control units arranged in this way may be symmetrically arranged with respect to the center of the second plate.

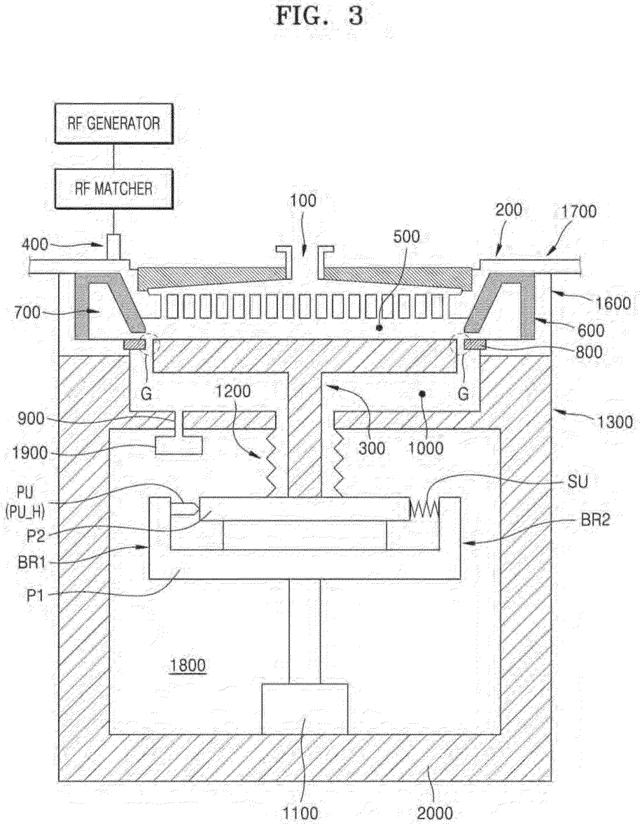

Referring to FIG. 3, a position control unit of the substrate processing apparatus may include a horizontal position control unit PU_H. The horizontal position control unit PU_H may be configured to horizontally move the second plate P2 with respect to the first plate P1. A fixed body of the horizontal position control unit PU_H may be connected to the first plate P1, and the moving body of the horizontal position control unit PU_H may contact one side surface of the second plate P2.

In an optional embodiment, the substrate processing apparatus may further include a first bracket BR1 connected to the first plate P1. The first bracket BR1 may be configured separately from the first plate P1 or may be integrally formed with the first plate P1. In this case, the horizontal position control unit PU_H may be fixed to the first bracket BR1. The horizontal position control unit PU_H fixed to the first plate P1 through the first bracket BR1 may apply a force toward one side surface of the second plate P2, and by the force, the second plate P2 may move in the horizontal direction.

The support unit SU may be on the other side surface of the second plate P2. In some embodiments, the horizontal position control unit PU_H and the support unit SU may be symmetrically arranged with respect to the center of the second plate P2. Accordingly, the support unit SU may generate a support force (e.g., an elastic force) corresponding to a force applied toward a side surface of the second plate P2 generated by the horizontal position control unit PU_H.

In an optional embodiment, the substrate processing apparatus may further include a second bracket BR2 connected to the first plate P1. The second bracket BR2 may be configured separately from the first plate P1 or may be integrally formed with the first plate P1. In this case, the support unit SU may be fixed to the second bracket BR2. The support unit SU fixed to the first plate P1 through the second bracket BR2 may support the second plate P2 in the horizontal direction while allowing movement of the second plate P2 by the force generated by the horizontal position control unit PU_H.

In some embodiments, as shown in FIG. 2, each of the horizontal position control unit PU_H and the support unit SU may be one, and the support unit SU may be arranged to face the horizontal position control unit PU_H. In this case, the support unit SU may generate a support force (e.g., an elastic force equal to the force described above) corresponding to a force applied toward a side surface of the second plate P2 generated by the horizontal position control unit PU_H.

In another example, as shown in FIG. 10, the number of the horizontal position control unit PU_H may be two and the number of the support unit SU may be one (PU_H1, PU_H2, and SU_H1 in FIG. 10, respectively), and two horizontal position control units PU_H and one support unit SU may be symmetrically arranged to have an interval of 120 degrees from each other. In this case, the support unit SU may generate a support force (e.g., an elastic force) equal to the sum of two kinds of forces applied toward two side surfaces of the second plate P2 generated by the two horizontal position control units PU_H.

Although not shown in the drawings, any number of horizontal position control units PU_H and support units SU may be arranged. For example, two support units SU and two horizontal position control units PU_H may be arranged, and in another example, two support units SU and four horizontal position control units PU_H may be arranged. The horizontal position control unit PU_H and the support unit SU arranged in this way may be symmetrically arranged to have the same angular distance from each other.

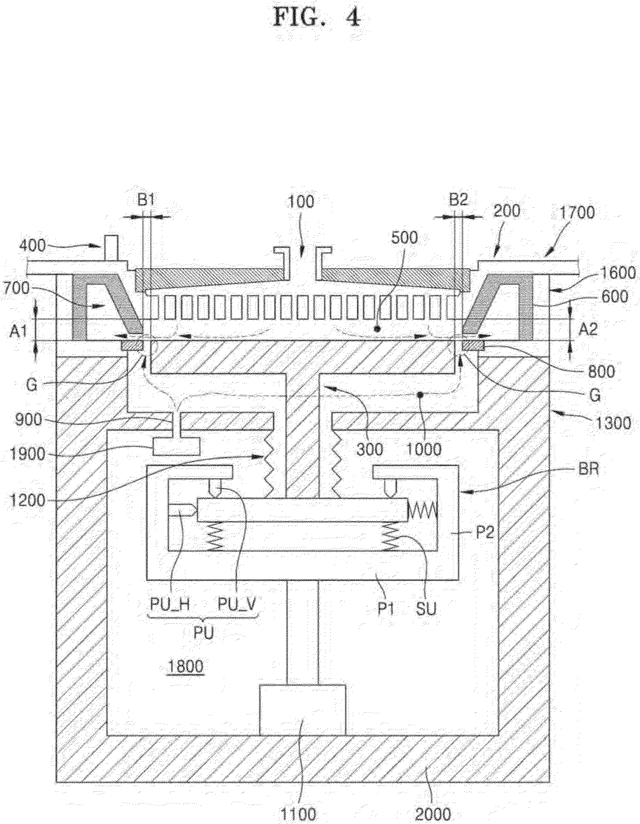

Referring to FIG. 4, a process gas introduced through the first gas inlet 100 may be supplied to the reaction space 500 and the substrate through the gas supply unit 200. For uniform processing of the substrate, it may be desirable to keep constant the distance between a lower surface of the gas supply unit 200 and an upper surface of the substrate on the substrate mounting unit 300. In other words, a distance A1 between the substrate mounting unit 300 and the gas supply unit 200 at one end of the substrate mounting unit 300 needs to be equal to a distance A2 between the substrate mounting unit 300 and the gas supply unit 200 at the other end of the substrate mounting unit 300 (i.e., A1=A2).

On the other hand, widths B1 and B2 of the gap G between the substrate supporting apparatus 3 and the ring 8 remain the same (i.e., B1=B2), thereby balancing the pressure between the reaction space 500 and the lower space 1000 over the entire section of the gap G.

However, as described above, in a high temperature process, a mismatch, that is, misalignment, of each portion of a reactor occurs due to a difference in thermal expansion due to the temperature difference between portions of a chamber and the reactor. For example, due to a difference in thermal expansion between an upper wall 1700 of the chamber, an upper reactor 1600, a lower reactor 1300, and a lower wall 2000 of the chamber, misalignment between components of the reactor may occur, which may cause tilting of the gas supply unit 200 or a shift in a centering position (center of symmetry) of the substrate mounting unit 300 with respect to the ring 800. In other words, the distances A1 and A2 of the reaction space 500 may not be constant over the entire section (A1≠A2), and/or the widths B1 and B2 of the gap G may not be constant over the entire section (B1≠B2).

In addition, in a high temperature process, because a temperature difference between the substrate mounting unit 300 and the ring 800 is great (e.g., the temperature of the substrate mounting unit 300 is about 500° C., and the temperature of the ring 800 is about 200° C.), the temperature distribution in the substrate mounting unit 300 may vary according to an alignment state of the substrate mounting unit 300 and the ring 800. This is because the closer the ring 800 is to the substrate mounting unit 300, the greater the influence on thermal conductivity of the substrate mounting unit 300.

As such, when the width of the reaction space 500 is not constant (A1≠A2) or the width of the gap G is not constant (B1≠B2), non-uniformity of a thin film on the substrate, particularly, non-uniformity of a thin film at the edge of the substrate, may be caused, and a defect rate of a semiconductor device may be increased. Therefore, there is a need for a method of compensating for the substrate mounting unit 300 such that the width of the reaction space 500 is kept constant (A1=A2) in response to the tilting of the gas supply unit 200 that occurs in high temperature and compensating for movement of the center of the substrate mounting unit 300 with respect to the ring 800 such that the width of the gap G is constant (B1=B2).

In addition, in order to solve a misalignment problem caused by thermal deformation caused by such a high-temperature process or vacuum force applied to the substrate processing apparatus, there is a need for a method of correcting such deformation/misalignment during processing without stopping the operation of the substrate processing apparatus because it takes a lot of time to stop the operation of the substrate processing apparatus, make corrections through maintenance work, and restore the substrate processing apparatus back to its original state, which significantly reduces the operating efficiency of the substrate processing apparatus.

The substrate processing apparatus shown in FIG. 4 is an apparatus capable of calibrating the substrate mounting unit 300 during the process, an embodiment of a substrate processing apparatus in which both the vertical position control unit PU_V of FIG. 2 and the horizontal position control unit PU_H of FIG. 3 are implemented is shown.

When the width of the reaction space 500 is not constant during the process (A1≠A2), the second plate P2 may be tilted using the vertical position control unit PU_V of the substrate processing apparatus. In addition, when the width of the gap G is not constant during the process (B1≠B2), a distance between the second plate P2 and the ring 800 may be adjusted using the horizontal position control unit PU_H of the substrate processing apparatus.

Tilting and/or spacing adjustment performed during the process may be performed while the substrate is unloaded, for example, during an idle state. For example, during the idle state in the process, fine calibration of the substrate mounting unit 300 may be performed by an operator entering a chamber space 1800 and operating the position control unit PU. As described above, the reaction space 500 and the lower space 1000 in a high temperature and/or vacuum state may be separated from the chamber space 1800 by the stretchable portion 1200, so that an operator may directly enter the chamber space 1800. In another example, by remotely controlling the position control unit PU during the idle state or during substrate processing, fine calibration of the substrate mounting unit 300 may be performed without an operator entering the chamber space 1800.

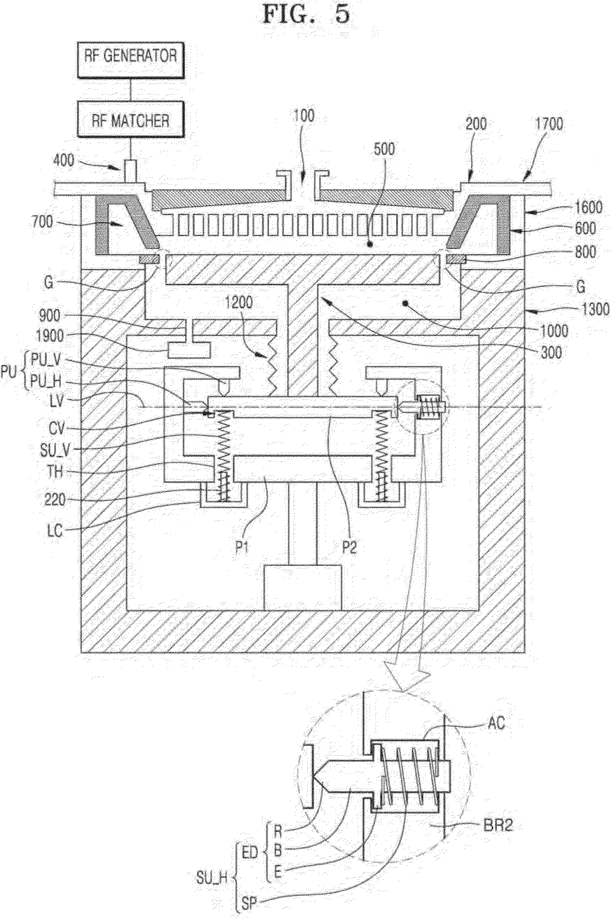

FIG. 5 is a view of a substrate processing apparatus according to other embodiments. The substrate processing apparatus according to the embodiments may be a variation of the substrate processing apparatus according to the above-described embodiments. Hereinafter, repeated descriptions of the embodiments will not be given herein.

Referring to FIG. 5, the substrate processing apparatus may further include a lower cover LC. The lower cover LC may be installed to be fixed to the first plate P1. A support unit SU_V including a coil-shaped elastic member may be accommodated in the lower cover LC. In an optional embodiment, the lower cover LC may include a protrusion 220, and one end of the coil-shaped elastic member may be inserted onto the protrusion 220. Such an insertion structure may contribute to fixing the support unit SU_V, which is an elastic member, to the first plate P1.

In some embodiments, the first plate P1 may include a through hole TH, and the support unit SU_V including the coil-shaped elastic member may extend from the lower cover LC toward the second plate P2 through the through hole TH of the first plate P1. In this case, a side surface of the support unit SU_V and a side surface of the through hole TH of the first plate P1 may be apart from each other, i.e. a first separation space. During tilting and/or horizontal movement of the second plate P2, through this first separation space, contact between the support unit SU_V and a side surface of the through hole TH of the first plate P1 may be prevented, and the second plate P2 is easier to tilt and move.

In an additional embodiment, the support unit SU_V may extend through at least a portion of the second plate P2. For example, the second plate P2 may include a concave portion CV on a lower surface thereof, and an elastic member constituting the support unit SU may contact the concave portion CV. In this case, in the concave portion CV, a side surface of the support unit SU may be apart from a side surface of the concave portion CV of the second plate P2, i.e. a second separation space. Contact between the support unit SU_V and the second plate P2 may be prevented during tilting and/or horizontal movement of the second plate P2 through this second separation space.

In some embodiments, a support unit SU_H may extend through at least a portion of the second bracket BR2. For example, the second bracket BR2 may include an accommodating portion AC in a side thereof, and the support unit SU_H may be accommodated in the accommodating portion AC. In some embodiments, the side surface of the support unit SU_H may be apart from the upper surface/lower surface of the accommodating portion AC of the second bracket BR2, i.e. a third separation space. Contact between the support unit SU_H and the second bracket BR2 may be prevented during the tilting and/or horizontal movement of the second plate P2 through this third separation space, and the tilting and movement of the second plate P2 becomes easier.

In another embodiment, the support unit SU_H may include an elastic member SP and an elastic force transmission unit ED connected to the elastic member SP. The elastic force transmission unit ED may be configured to apply an elastic force generated by the elastic member SP to a side surface of the second plate P2. In an optional embodiment, the elastic member SP may directly contact a side surface of the second plate P2 without the elastic force transmission unit ED. In this case, the elastic force of the elastic member SP may be directly transmitted to the second plate P2.

The elastic force transmission unit ED may contribute to stably supporting the second plate P2 when applying the elastic force of the elastic member SP to the second plate P2. For example, when the elastic member SP is in direct contact with a side surface of the second plate P2 and is a coil-type elastic member, because there is no supporting member for supporting the elastic member SP, a contact point between the elastic member SP and the second plate P2 may be different from a contact point between the horizontal position control unit PU_H and the second plate P2. In this case, by introducing the elastic force transmission unit ED as a supporting member of the elastic member SP to have a contact point corresponding to a contact point level LV between the horizontal position control unit PU_H and the second plate P2, the second plate P2 may be stably supported by the support unit SU.

For example, the horizontal position control unit PU_H may have a round first end. In this case, the elastic force transmission unit ED may also have a round second end, and the horizontal position control unit PU_H and the elastic force transmission unit ED may be arranged such that the first end and the second end have the same contact point level LV. In this case, the first end of the horizontal position control unit PU_H and the second end of the elastic force transmission unit ED may contact a side surface of the second plate P2 at the same contact point level LV.

In some embodiments, in order to transmit the elastic force of the elastic member SP to the side surface of the second plate P2 while the elastic force transmission unit ED is connected to the second bracket BR2, the elastic member SP and the elastic force transmission unit ED may be inserted into the accommodating portion AC of the second bracket BR2. In this case, the elastic force transmission unit ED may protrude from the side surface of the second bracket BR2 through the accommodating portion AC of the second bracket BR2 to contact the side surface of the second plate P2.

A specific exemplary shape of the elastic force transmission unit ED is shown on the lower right of FIG. 5. Referring to the portion, in an optional embodiment, the elastic force transmission unit ED may include a body portion B inserted into the elastic member SP, a round portion R connected to the body portion B and having a round end, and an extension E protruding from the body portion B. The extension E of the elastic force transmission unit ED may be in contact with the elastic member SP, and the elastic force of the elastic member SP may be transmitted to the elastic force transmission unit ED by the extension E.

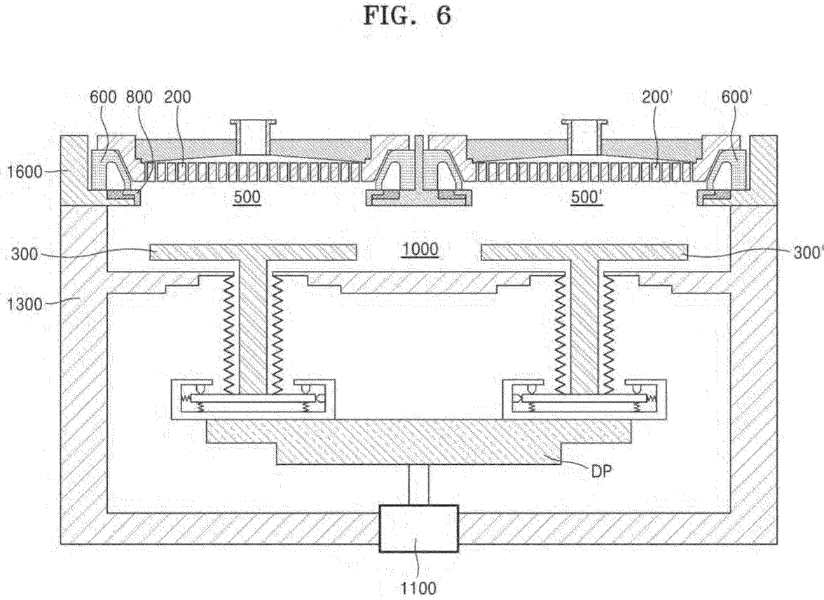

FIGS. 6 to 9 are views of a substrate processing apparatus according to other embodiments. The substrate processing apparatus according to these embodiments is a modification of the substrate processing apparatus according to the above-described embodiments and relates to a substrate processing apparatus capable of processing a plurality of substrates simultaneously. Hereinafter, repeated descriptions of the embodiments will not be given herein.

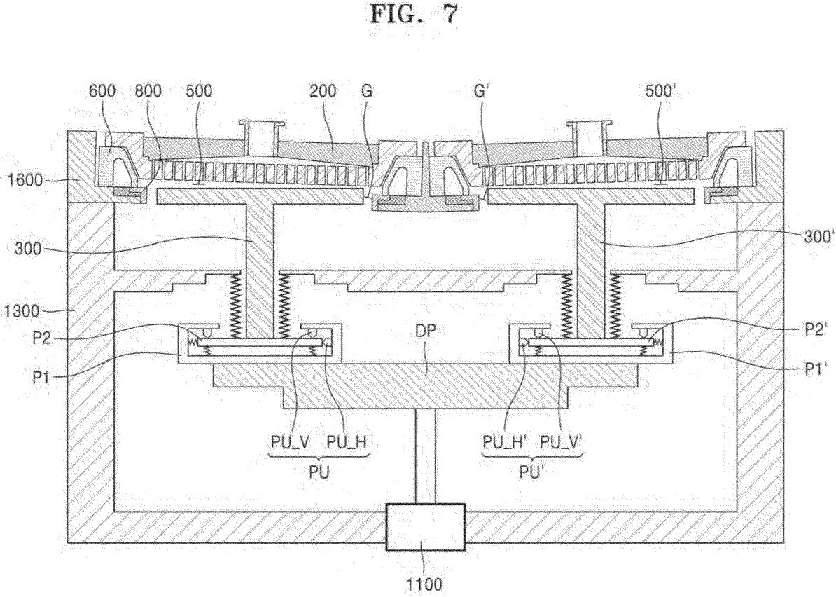

Referring to FIG. 6, the substrate processing apparatus may have a structure in which the upper body 1600 is installed on the lower body 1300, and the exhaust unit 600 and the gas supply unit 200 are sequentially stacked on the upper body 1600. The first reaction space 500 for processing the first substrate may be defined by the first substrate mounting unit 300, the first exhaust unit 600, and the first gas supply unit 200. A second reaction space 500' for processing the second substrate may be defined by a second substrate mounting unit 300', a second exhaust unit 600', and a second gas supply unit 200' (See FIG. 7).

A filling gas supplied from the lower space 1000 below the reaction space 500 may be supplied to the first reaction space 500 and the second reaction space 500', respectively. In more detail, as shown in FIG. 7, the filling gas may be supplied to the first reaction space 500 through a first gap G (in FIG. 7) between the first substrate mounting unit 300 and the first ring 800. The filling gas may be supplied to the second reaction space 500' through a second gap G′ (in FIG. 7) between the second substrate mounting unit 300' and the second ring 800. Therefore, mixing of gas in the first reaction space 500 with gas in the second reaction space 500' may be prevented by the filling gas during the process, and the first reaction space 500 may be substantially separated from the second reaction space 500'.

The first plate P1 connected to the first substrate mounting unit 300 and a first plate P1' connected to the second substrate mounting unit 300' may be connected to a driving plate DP. The driving unit 1100 may be configured to raise/lower the driving plate DP, and by the operation of the driving unit 1100, the first substrate mounting unit 300 and the second substrate mounting unit 300' may be raised or lowered at the same time. In addition, when the driving plate DP is moved by the operation of the driving unit 1100, both the first plates P1 and P1' and the second plates P2 and P2' may move at the same time.

In contrast to the driving unit 1100, the position control unit PU of the first substrate mounting unit 300 connected between the first plate P1 and the second plate P2 may move only the first substrate mounting unit 300. Similarly, a position control unit PU' of the second substrate mounting unit 300' connected between the first plate P1' and the second plate P2' may move only the second substrate mounting unit 300'. In addition, the position control unit PU may move only the second plate P2 without moving the first plate P1.

Referring to FIG. 6, a state in which the driving plate DP is lowered is illustrated. The first substrate mounting unit 300 and the second substrate mounting unit 300' descend together by the lowering of the driving plate DP, and in this state, a loading operation of a substrate may be performed to start processing of the substrate.

Referring to FIG. 7, the driving plate DP is raised by a raising operation of the driving unit 1100, and accordingly, the first substrate mounting unit 300 and the second substrate mounting unit 300' are raised together to form the first reaction space 500 and the second reaction space 500'. Thereafter, a processing operation of a substrate may be performed. The processing operation may be performed under a high temperature and/or vacuum environment, and deformation of the substrate processing apparatus may occur due to the high temperature and/or vacuum environment.

FIG. 7 shows an example in which sagging of the gas supply unit 200 occurs as an example of such deformation. As shown in FIG. 7, a phenomenon in which the center of the upper body 1600 sags may occur in a high temperature and/or vacuum process. Due to this, the gas supply unit 200 is tilted, and widths of the first reaction space 500 and the second reaction space 500' may not be constant.

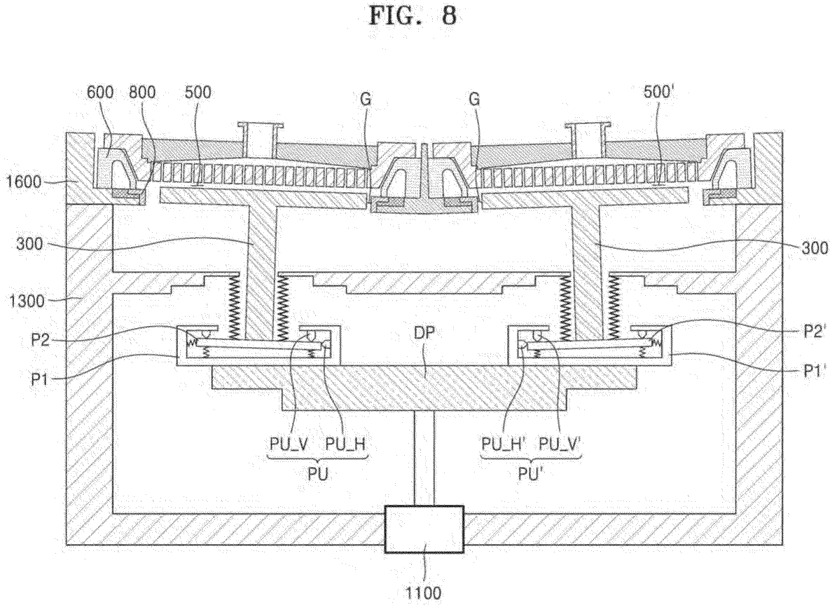

FIG. 8 shows a result of performing a tilting operation as a fine correction operation of the substrate mounting unit 300 with respect to the tilting of the gas supply unit 200. To this end, an operation (e.g., an operation of extending a length of a corresponding position control unit) of moving a portion of the second plate P2 close to the center of the substrate processing apparatus in a downward direction using the vertical position control unit PU_V may be performed. Optionally, an operation of moving a portion of the second plate P2 close to the periphery of the substrate processing apparatus in an upward direction using the vertical position control unit PU_V (e.g., an operation of reducing a length of a corresponding position control unit) may be performed.

In another example, a combination of the above-described operations may be performed, and an example thereof is shown in FIG. 8. That is, an operation of extending a length of a position control unit close to the center of the substrate processing apparatus and simultaneously reducing a length of a position control unit adjacent to the periphery of the substrate processing apparatus may be performed. Accordingly, the substrate mounting unit 300 may be tilted to correspond to the tilting of the gas supply unit 200 due to sagging of the center of the upper body 1600, and the widths of the first reaction space 500 and the second reaction space 500' may be kept constant.

In an optional embodiment, after the above-described tilting operation, a compensation operation using the horizontal position control unit PU_H may be performed. For example, when the second plate P2 is tilted by the movement of the vertical position control unit PU_V, displacement of the substrate mounting unit 300 in the horizontal direction may occur due to the tilting operation. The compensation operation may be defined as an operation for preventing the gap G between the ring 800 and the substrate mounting unit 300 from becoming non-uniform due to such a displacement.

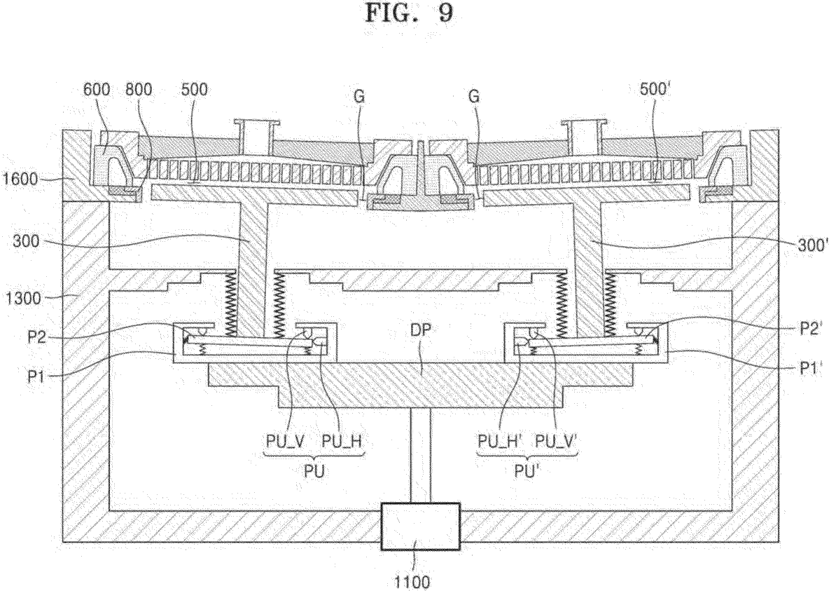

As shown in FIG. 8, when the substrate mounting unit 300 is tilted toward the center of the substrate processing apparatus, the substrate mounting unit 300 may move in a first horizontal direction toward the center of the substrate processing apparatus by such tilting. In this case, as shown in FIG. 9, the horizontal position control unit PU_H may move the second plate P2 in a second horizontal direction opposite to the first horizontal direction.

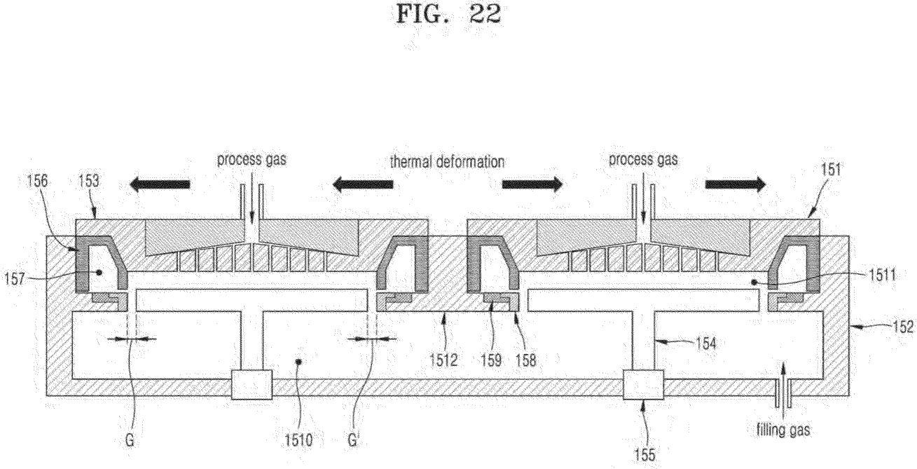

For example, as shown in FIG. 23, assuming that a length from the center of a second plate (P2 in FIGS. 8 and 3 in FIG. 23) to a contact point between the second plate (P2 in FIGS. 8 and 3 in FIG. 23) and a vertical position control unit (PU_V in FIGS. 8 and 7 in FIG. 23) is R1 as a first length, a length from the second plate to a substrate mounting unit (300 in FIGS. 8 and 1 in FIG. 23) is R2 as a second length, and the vertical position control unit (P2 in FIGS. 8 and 3 in FIG. 23) moves by b as a third length at the contact point, a horizontal position control unit (PU_H in FIG. 8 and 8 in FIG. 23) may perform the above-described compensation operation by moving the second plate (P2 in FIGS. 8 and 3 in FIG. 23) by a distance equal to a value obtained by multiplying the second length R2 by a third length b and dividing the first length R1. In more detail, as shown in FIG. 23, when the vertical position control unit PU_V (7 in FIG. 23) moves by the third length b in the vertical direction from the contact point, the second plate P2 (3 in FIG. 23) and a substrate mounting unit 1 (in FIG. 23) may be tilted by angle α. If the amount of movement in a first horizontal direction of the substrate mounting unit 1 (in FIG. 23) generated by such tilting is x, tan α=x/R2= b/R1, so the relation of x=b*R2/R1 may be established. Accordingly, the horizontal position control unit PU_H (8 in FIG. 23) may maintain the gap G (in FIG. 23) between a ring 2 (in FIG. 23) and the substrate mounting unit 1 (in FIG. 23) uniform (G=G′) by moving the second plate P2 (3 in FIG. 23) by x=b*R2/R1 in the second horizontal direction opposite to the first horizontal direction.

FIG. 10 is a view of a substrate processing apparatus according to other embodiments. The substrate processing apparatus according to the embodiments may be a variation of the substrate processing apparatus according to the above-described embodiments. Hereinafter, repeated descriptions of the embodiments will not be given herein.

Referring to FIG. 10, the second plate P2 on the first plate P1 is shown. The second plate P2 may include a first protrusion PR1, a second protrusion PR2, and a third protrusion PR3, which may be symmetrically arranged to have an angular distance of 120 degrees from each other. Brackets BR1, BR2, and BR3 and lower covers LC1, LC2, and LC3 may be installed to be fixed to the first plate P1 at positions where the first protrusion PR1, the second protrusion PR2, and the third protrusion PR3 are arranged. Lids LD1, LD2, and LD3 may be installed to be fixed to the second plate P2 at positions where the first protrusion PR1, the second protrusion PR2, and the third protrusion PR3 are arranged. Because the brackets BR1, BR2, and BR3 and the lower covers LC1, LC2, and LC3 have been described in the above-described embodiment, their descriptions will be omitted.

The lids LD1, LD2, and LD3 may be configured to be arranged on upper surfaces of the protrusions respectively to provide points of contact with a position control unit and/or a support unit. In an optional embodiment, the lid may be implemented to be integrated with the protrusion. In another embodiment, as shown in FIG. 10, the lid may be implemented as a separate configuration and installed to be fixed to the second plate P2.

In more detail, a first position control unit PU_V1 on the first protrusion PR1 may contact an upper surface of the first lid LD1 on the first protrusion PR1 to form a first contact point. Accordingly, the first position control unit PU_V1 between the first bracket BR1 and an upper surface of the first protrusion PR1 may change the position of the first protrusion PR1 of the second plate P2 through the first contact point.

A second position control unit PU_V2 on the second protrusion PR2 may contact an upper surface of the second lid LD2 on the second protrusion PR2 to form a second contact point. Accordingly, the second position control unit PU_V2 between the second bracket BR2 and an upper surface of the second protrusion PR2 may change the position of the second protrusion PR2 of the second plate P2 through the second contact point.

The third position control unit PU_V3 on the third protrusion PR3 may contact an upper surface of the third lid LD3 on the third protrusion PR3 to form a third contact point. Accordingly, the third position control unit PU_V3 between the third bracket BR and an upper surface of the third protrusion PR3 may change the position of the third protrusion PR3 of the second plate P2 through the third contact point.

In addition, the fourth position control unit PU_H1 next to the first protrusion PR1 may contact a side surface of the first lid LD1 on the first protrusion PR1 to form a fourth contact point. Accordingly, the fourth position control unit PU_H1 between the first bracket BR1 and a side surface of the first protrusion PR1 may change the position of the first protrusion PR1 of the second plate P2 through the fourth contact point.

A fifth position control unit PU_H2 next to the second protrusion PR2 may contact a side surface of the second lid LD2 on the second protrusion PR2 to form a fifth contact point. Accordingly, the fifth position control unit PU_H2 between the second bracket BR2 and a side surface of the second protrusion PR2 may change the position of the second protrusion PR2 of the second plate P2 through the fifth contact point.

The first support unit SU_H1 next to the third protrusion PR3 may contact a side surface of the third lid LD3 on the third protrusion PR3 to form a sixth contact point. Accordingly, the first support unit SU_H1 between the third bracket BR and a side surface of the third protrusion PR3 may change the position of the third protrusion PR3 of the second plate P2 through the sixth contact point.

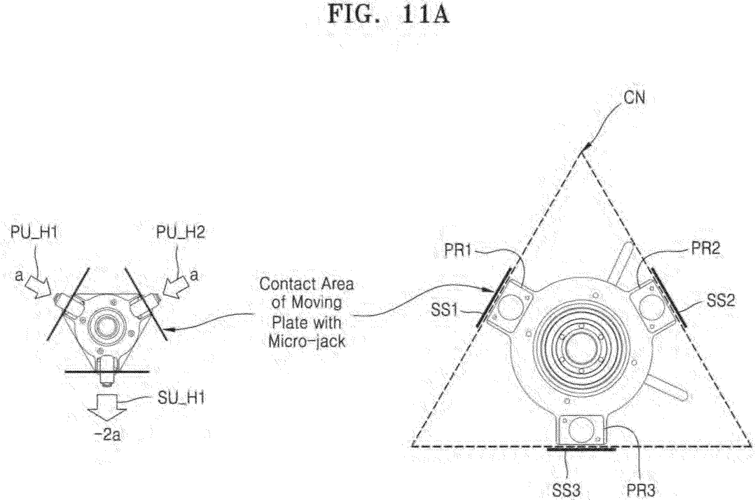

In more detail, the first support unit SU_H1 may change the position of the third protrusion PR3 by passively moving in response to active movement of the fourth position control unit PU_H1 and the fifth position control unit PU_H2, and a detailed operation thereof will be described later with reference to FIGS. 11A and 11B.

In addition, a second support unit SU_V1 below the first position control unit PU_V1 may penetrate the first plate P1 and the second plate P2 to contact the first lid LD1 to form a seventh contact point. Accordingly, the second support unit SU_V1 between the first lower cover LC1 and the first lid LD1 may change the position of the first protrusion PR1 of the second plate P2 through the seventh contact point.

In the same manner, a third support unit SU_V2 below the second position control unit PU_V2 may penetrate the first plate P1 and the second plate P2 and contact the second lid LD2 to change the position of the second protrusion PR2 of the second plate P2, and a fourth support unit SU_V3 below the third position control unit PU_V3 penetrates the first plate P1 and the second plate P2 and contacts the third lid LD3 to change the position of the third protrusion PR3 of the second plate P2.

FIGS. 11A and 11B illustrate passive movement of the first support unit SU_H1 in response to active movement of the fourth position control unit PU_H1 and the fifth position control unit PU_H2 of FIG. 10. The left portion of FIG. 11 is a plan view of the first plate P1 and the second plate P2 of FIG. 10 viewed from above, and the right portion of FIG. 11 is a cross-sectional schematic diagram of a side portion of the second plate P2 in such a plan view.

Referring to FIG. 10 and FIGS. 11A and 11B, as described above, two horizontal position control units (i.e., the fourth position control unit PU_H1 and the fifth position control unit PU_H2) and one support unit (i.e., the first support unit SU_H1) may be symmetrically arranged with respect to the center of the second plate P2. In more detail, as shown in FIG. 10, they may be arranged to have an interval of 120 degrees from each other. In addition, as described above in FIG. 5, the fourth position control unit PU_H1, the fifth position control unit PU_H2, and the first support unit SU_H1 may have end portions at the same level (LV of FIG. 5). In other words, the fourth contact point, the fifth contact point, and the sixth contact point may be located at the same height as each other.

When the fourth position control unit PU_H1 and the fifth position control unit PU_H2 move by a first distance toward the center of the first plate P1 through the fourth and fifth contact points, the second plate P2 may move toward the first support unit SU_H1 by a second distance that is twice the first distance. The movement of the second plate P2 may be compared to movement of a triangular plate.

In more detail, as shown in FIG. 11A, when side surfaces of the first protrusion PR1, the second protrusion PR2, and the third protrusion PR3 providing the fourth contact point, the fifth contact point, and the sixth contact point, respectively, are considered to have respective planes, the second plate P2 may be viewed as a plate having an equilateral triangle shape. Referring to FIGS. 10 and 11A, as the fourth position control unit PU_H1 fixed to the first plate P1 through the first bracket BR1 moves toward the center of the first plate P1 by the first distance and as the fifth position control unit PU_H2 fixed to the first plate P1 through the second bracket BR2 moves toward the center of the first plate P1 by the first distance, the second plate P2 moves toward the first support unit SU_H1 by the second distance, and it can be seen that the second distance is twice the first distance in consideration of a proportional relationship of triangles as shown in FIG. 11B. That is, in some embodiments, the second plate P2 may include a first side surface SS1 providing the fourth contact point, a second side surface SS2 providing the fifth contact point, and a third side surface SS3 providing the sixth contact point. The second plate P2 may be implemented to form an equilateral triangle when the first side surface SS1, the second side surface SS2, and the third side surface SS3 extend from each other. It should be noted that the formation of such an equilateral triangle is irrelevant to the presence or absence of the protrusions PR1, PR2, and PR3, and thus for example, the second plate P2 may be implemented to have an equilateral triangle shape.

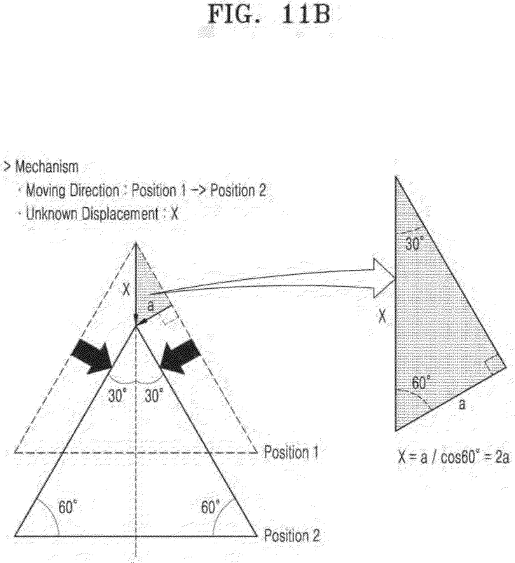

FIG. 12 is a flowchart illustrating a substrate processing method according to other embodiments. The substrate processing method according to the embodiments may be performed using the substrate processing apparatus according to the above-described embodiments. Hereinafter, repeated descriptions of the embodiments will not be given herein.

Referring to FIG. 12, in operation S121, first, first substrates of a first lot are processed. In some embodiments, the processing of the first substrates may be performed under a high temperature and/or vacuum environment. Deformation or misalignment of components of a substrate processing apparatus may occur during processing of the first substrates due to the high temperature and/or vacuum environment or due to a design lifetime limit of the substrate processing apparatus.

In operation S122, after the first substrates are processed, the first substrates are unloaded. A first plate and a second plate may descend together by the driving of a driving unit, and substrates mounted on a substrate mounting unit may be unloaded. When a substrate processing apparatus as shown in FIG. 6 is used, a driving plate will be lowered by the driving of the driving unit, and a plurality of substrate mounting units will be lowered together.

In operation S123, during the unloaded state of the substrates, that is, during an idle state, second substrates of a second lot may be transferred to a reaction chamber. The high temperature and/or vacuum environment described above may be maintained during the idle state in some embodiments. On the other hand, in operation S124, a fine calibration operation of the substrate mounting unit may be performed during the idle state. During the fine correction operation, the first plate may be fixed, and the second plate may be moved by a position control unit.

Thereafter, in operation S125, the substrates are loaded and the first plate and the second plate are raised together. In an embodiment in which a plurality of substrate mounting units are implemented, a second plate of a first substrate mounting unit and a second plate of a second substrate mounting unit may move in the same direction (i.e. upward towards a reaction space) during substrate loading. On the other hand, during a fine correction operation, the second plate of the first substrate mounting unit and the second plate of the second substrate mounting unit may move in different directions. For example, during the fine calibration operation, the second plate of the first substrate mounting unit may move in a clockwise direction, the second plate of the second substrate mounting unit may move in a counterclockwise direction. Thereafter, in operation S126, processing of the second substrates of the second lot is performed as subsequent substrate processing.

In another embodiment, the substrate unloading operation (operation S122) and the fine calibration operation of the substrate support unit (operation S124) may be performed at the same time. In this case, the first plate and the second plate may move in different directions. That is, because the first plate and the second plate are simultaneously lowered during the substrate unloading operation, but the first plate is fixed and the second plate is moved during the fine calibration operation, so when these are performed simultaneously, a moving direction (downward direction) of the first plate and a moving direction (downward direction + fine correction direction) of the second plate may be different from each other as a result.

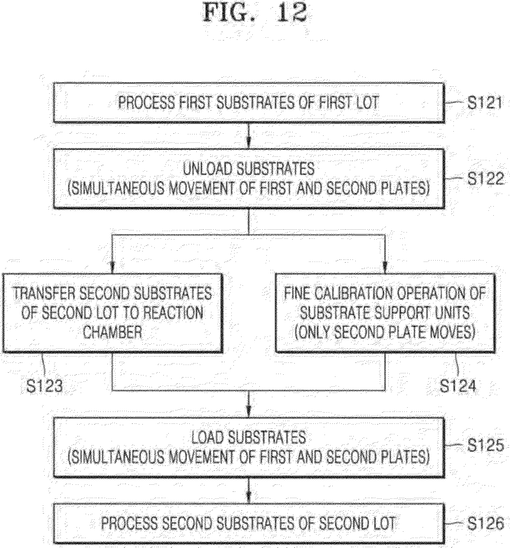

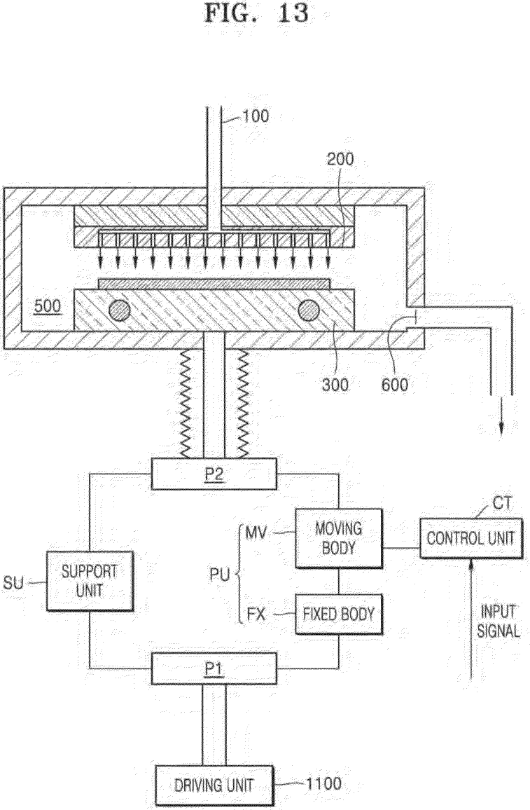

FIGS. 13 to 14 are views of a substrate processing apparatus according to other embodiments. The substrate processing apparatus according to the embodiments may be a variation of the substrate processing apparatus according to the above-described embodiments. Hereinafter, repeated descriptions of the embodiments will not be given herein.

Referring to FIGS. 13 and 14, a substrate processing apparatus having a shape different from those of the above-described embodiments is shown. The substrate processing apparatus may also include the first gas inlet 100, the gas supply unit 200, and the substrate mounting unit 300, the reaction space 500 may be formed between the gas supply unit 200 and the substrate mounting unit 300, and gas in the reaction space 500 may be exhausted through the exhaust unit 600. In addition, the first plate P1 may be moved by the driving of the driving unit 1100.

As shown in FIG. 13, the substrate processing apparatus may further include a control unit CT configured to control a moving body MV of the position control unit PU. The control unit CT may move the moving body MV based on an input signal. In this case, a relative position of the second plate P2 with respect to the first plate P1 may be changed by moving the second plate P2 connected to the moving body MV, and as a result, the substrate mounting unit 300 may be finely calibrated.

The input signal input to the control unit CT may be a wired signal or a wireless signal. In this case, the fine calibration operation of the substrate mounting unit 300 may be remotely performed without an operator entering a chamber space. Because the operator does not enter the chamber space, the fine calibration operation may be performed not only in an idle state but also during substrate processing.

In a further embodiment, the fine calibration operation of the substrate mounting unit 300 may be performed automatically. For example, as shown in FIG. 14, the control unit CT may move the moving body MV of the position control unit PU based on a sensing signal generated by a sensor (not shown) that detects deformation and/or misalignment of a component of the substrate processing apparatus. In more detail, the substrate processing apparatus may include a conversion portion CV configured to generate an input signal for performing desired tilting and/or horizontal movement of the substrate mounting unit 300 based on the sensing signal. The conversion portion CV may search for an input signal matching the sensing signal from a database (e.g., a lookup table) stored in a storage unit DB, and may transmit the input signal to the control unit CT.

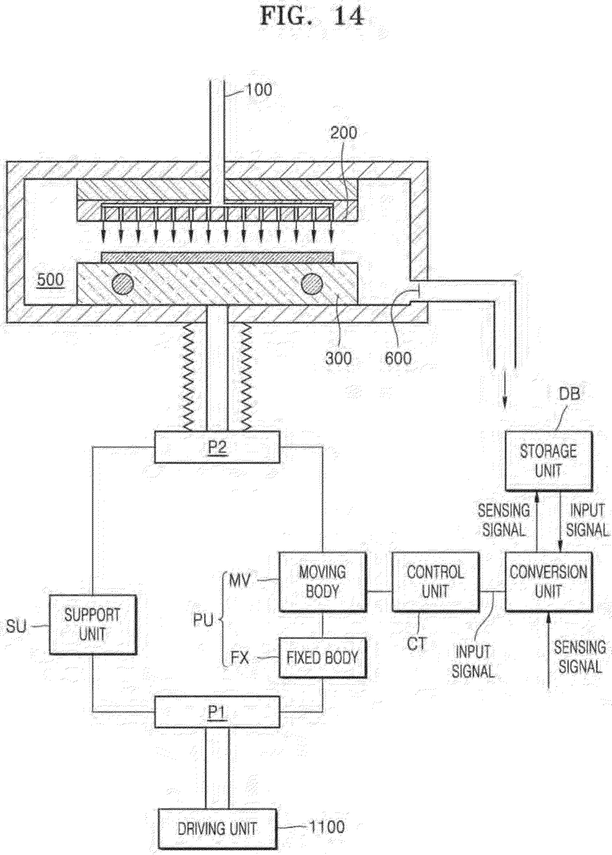

FIG. 15 is a view of a substrate processing apparatus according to the disclosure.

In FIG. 15, a reactor 151 includes a reactor wall 152, a gas supply unit 153, a heating block 154, a heating block support unit 155, an exhaust unit 156, and gas flow control rings 158 and 159. The gas supply unit 153 is seated on an upper surface of the exhaust unit 156, and the exhaust unit 156 is seated on one side surface of the reactor wall 152. The heating block 154 is supported by the heating block support unit 155, and a lower surface of the gas supply unit 153, a side surface of the exhaust unit 156, and an upper surface of the heating block 154 form a reaction space 1511. In FIG. 15. an external gas flow control ring 159 is on one side surface of the reactor wall 152 and an internal gas flow control ring 158 is seated on an upper surface of the external gas flow control ring 159. In FIG. 15, the exhaust unit 156 and the gas flow control rings 158 and 159 form an exhaust space 157. A gap is maintained at a certain interval between the heating block 154 and the internal gas flow control ring 158 (G1=G2). In a lower space 1510 of the reactor 151, a filling gas is supplied from the bottom of the reactor, and when gas is exhausted from the reaction space 1511 to the exhaust space 157 of the exhaust unit 156, the inflow of the gas into the reactor lower space 1510 through the gaps G1 and G2 is prevented by the filling gas. In FIG. 15, the heating block 154 and the heating block support unit 155 constitute a substrate support unit. In the disclosure, the heating block support unit 155 provides a member for constantly maintaining the reaction space 1511 (i.e. D1=D2) even at a high temperature without switching to a maintenance mode. In addition, in the disclosure, the heating block support unit 155 provides a member for maintaining a constant gap (i.e. G1=G2) between the heating block 154 and the internal gas flow control ring 158 even at a high temperature.

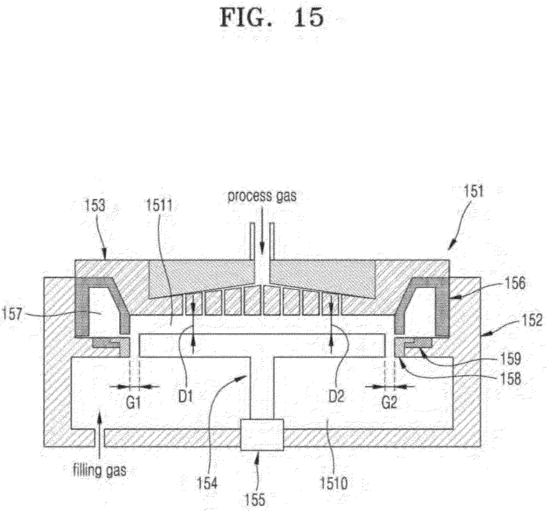

FIGS. 16A-16C are views illustrating an embodiment of a substrate support unit and a heating block support unit according to the disclosure. FIG. 16A shows the heating block 1 and a heating block support unit 2. FIG. 16B is an enlarged view of the heating block support unit 2, and FIG. 16C is a top view of the heating block support unit 2. In FIG. 16B, the heating block support unit 2 includes a moving plate 3 and a base plate 4 supporting the moving plate 3. One side surface of the moving plate 3 includes protrusions 6. An inner surface of a protrusion includes a concave space made of a step, and position control unit support units 10-a, 10-b, and 10-c are inserted thereinto. In FIG. 16B, brackets 5-a, 5-b, and 5-c are provided on respective one of side surfaces of the base plate 4 and provide position control units 7-a, 7-b, 7-c, 8-a, and 8-b and an alignment portion 9 with respect to the moving plate 3. A position control unit includes the vertical position control units 7-a, 7-b, and 7-c and the horizontal position control units 8-a and 8-b.

The moving plate 3 is provided with a groove into which a sealing member is inserted so that a reactor 151 (of FIG. 15) may be isolated from an external space. The first groove 13 is provided with a shielding unit connecting the moving plate 3 to a bottom surface of the reactor. For example, spaces among the moving plate 3, the heating block 1, and the reactor are blocked from the external space by providing a flexible shield such as bellows. In addition, a shielding unit is provided in a second groove 14 to block a cross section where the moving plate 3 and the heating block 1 meet from the external space. For example, an O-ring may be provided in the second groove.

Because the moving plate 3 is in direct contact with the heating block 1, the moving plate 3 is maintained at a high temperature in a high-temperature process. Accordingly, a coolant path is formed in the moving plate 3 so that the shielding unit provided in the first groove and/or the second groove is not cured by heat. A coolant inlet 11 and a coolant outlet 12 are provided on one surface of the moving plate 3.

In FIG. 16B, the base plate 4 is fixed to a heating block driving unit (not shown) fixed to the reactor and cannot move, whereas the moving plate 3 is movable in the horizontal direction by the position control units 7-a, 7-b, 7-c, 8-a, and 8-b, and tilting of the moving plate 3 about a moving axis is also possible.

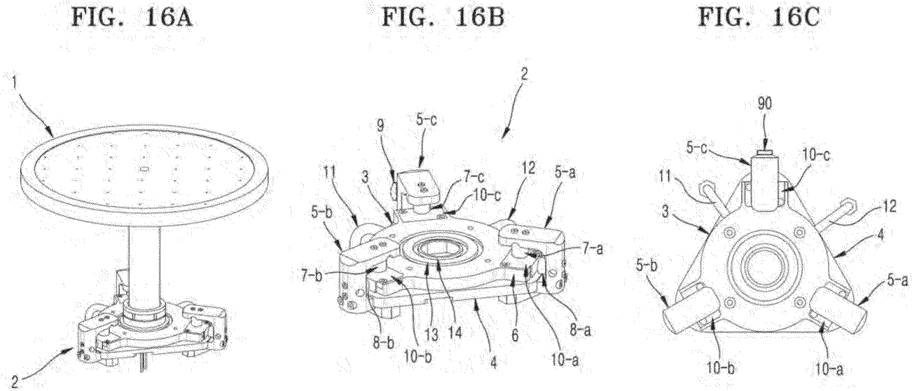

FIG. 17 is a view illustrating a movable direction and a tilting direction of the heating block 1 supported by the heating block support unit of FIGS. 16A-16C.

In FIG. 17, a heating block has 5 degrees of freedom by a moving plate and a position control unit provided on the moving plate. In other words, the heating block has a degree of freedom of lateral moving in three directions X, Y, and Z, and two degrees of freedom of tilting Θx and Θy around axes in X and Y directions. Referring to FIGS. 16A, 16B, 16C, and 17, a driving method will be described in more detail. When the two horizontal position control units 8-a and 8-b installed in the horizontal direction of the two brackets 5-a and 5-b of the moving plate 3 move in a forward direction (+), the horizontal position control units 8-a and 8-b push sides of the two position control unit support units 10-a and 10-b, and the two position control unit support units 10-a and 10-b and the moving plate 3 move in a direction in which the horizontal position control units 8-a and 8-b push. Any one of the horizontal position control units may move individually or simultaneously. When the two horizontal position control units 8-a and 8-b move simultaneously, the moving plate 3 horizontally moves in a vector sum direction of the applied direction. In addition, there may be a technical effect of more precisely controlling a horizontal moving direction by varying a movement distance of each position control unit. The horizontal position control units 8-a and 8-b may be at least one of a micro screw jack, a micro meter, or a leveling screw jack and facilitates precise positioning of the moving plate 3.

Meanwhile, the bracket 10-c includes an alignment control unit 9 instead of a position control unit. The alignment control unit 9 prevents excessive movement or an over-constraint state of the moving plate 3 in the horizontal direction by the horizontal position control units 8-a and 8-b. Therefore, the alignment control unit 9 may include a first elastic body. For example, the first elastic body of the alignment control unit 9 may be a spring, and over-constraint by the horizontal position control units 8-a and 8-b may be controlled by using an elastic force of the spring. In an embodiment, the spring may be an elastic body such as a coil spring or a plate spring, and the elastic force may be 20 kgf to 30 kgf.

Tilting adjustment of a heating block is made by movement of the vertical position control units 7-a, 7-b, and 7-c installed in the vertical direction on the three brackets 5-a, 5-b, and 5-c. In more detail, when the vertical position control units 7-a, 7-b, and 7-c move in the forward direction (+), the vertical position control units 7-a, 7-b, and 7-c push an upper surface of the position control unit support units 10-a, 10-b, and 10-c in the vertical direction, and the position control unit support units 10-a, 10-b, and 10-c and the moving plate 3 are moved in the vertical direction. Any one of the vertical position control units may move individually or simultaneously. In an embodiment, by varying a movement distance of each vertical position control unit, tilting in the vertical direction may be more precisely controlled. In order to precisely control the movement in the vertical direction, that is, tilting, the position control unit support units 10-a, 10-b, and 10-c may include a second elastic body. For example, the second elastic body of the position control unit support units 10-a, 10-b, and 10-c may be a spring, and over-constraint by the vertical position control units 7-a, 7-b, and 7-c may be prevented by using an elastic force of the spring. In an embodiment, the spring may be an elastic body such as a coil spring or a plate spring, and each elastic force may be 5 kgf to 15 kgf (total 5 kgf to 15 kgf × 3 EA = 15 kgf to 45 kgf). Therefore, by using the first elastic body and the second elastic body, an over-constrained state may be prevented, and deformation and damage of fixed components due to residual stress may be prevented.

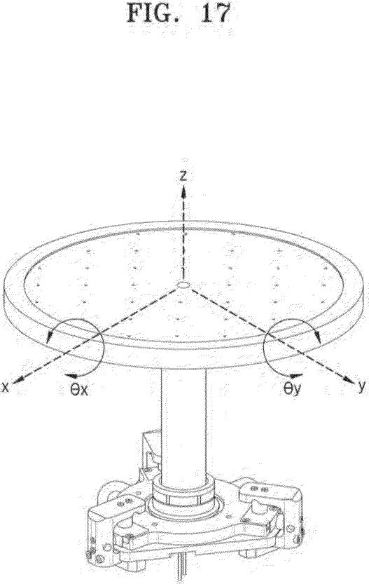

FIGS. 18A and 18B show views of a moving plate control unit including the bracket 5-a, 5-b, and 5-c, the horizontal position control units 8-a and 8-b, the alignment control unit 9, and the vertical position control units 7-a, 7-b, and 7-c.

In the perspective view of FIG. 18A, a concave space 13 is formed in a protrusion 6 of the moving plate 3. In an embodiment, the concave portion 13 may be a through hole penetrating the protrusion 6. A second elastic body 16 is inserted into the through hole, and the position control unit support units 10-a, 10-b, and 10-c are mounted on the second elastic body 16.

In FIGS. 18A and 18B, when the horizontal position control units 8-a and 8-b move in a horizontal direction, the position control unit support units 10-a and 10-b and the moving plate 3 are pushed in the horizontal direction, and the alignment control unit 9 precisely controls the horizontal movement of the moving plate 3 while controlling excessive movement or over-constraint of the moving plate 3 that moves horizontally by an elastic force of a first elastic body 15. As shown in FIGS. 18A and 18B, the second elastic body 16 and the through hole are apart from each other, and an end portion of the alignment control unit 9 in contact with the position control unit support unit 10-c protrudes from an outer wall of the bracket 5-c to facilitate horizontal movement of the moving plate 3. For example, as shown in FIG. 18A, the moving plate 3 may move horizontally by a separation distance between the second elastic body 16 and the through hole. In FIG. 18B, the separation distance is 1 mm to 9 mm, but is not limited thereto. In addition, because friction between the through hole and the second elastic body 16 may be prevented due to the gap, vertical movement and tilting of the movable plate 3 may be made easier. There is a protrusion on the side of the alignment control unit 9 so that coupling with the first elastic body 15 may be maintained.

On the other hand, in FIGS. 18A and 18B, when the vertical position control units 7-a, 7-b, and 7-c move in a vertical direction, the position control unit support units 10-a, 10-b, and 10-c and the moving plate 3 are pushed in the vertical direction, and when the moving plate 3 is tilted due to an elastic force of the second elastic body 16, the tilting of the moving plate 3 is precisely controlled while controlling excessive movement or over-constraint. As shown in FIGS. 18A and 18B, the moving plate 3 is apart from the base plate 4, so that the vertical movement or tilting of the moving plate 3 may be made easier. In the embodiment of FIG. 18B, the separation distance is 1 mm to 6 mm, but is not limited thereto.

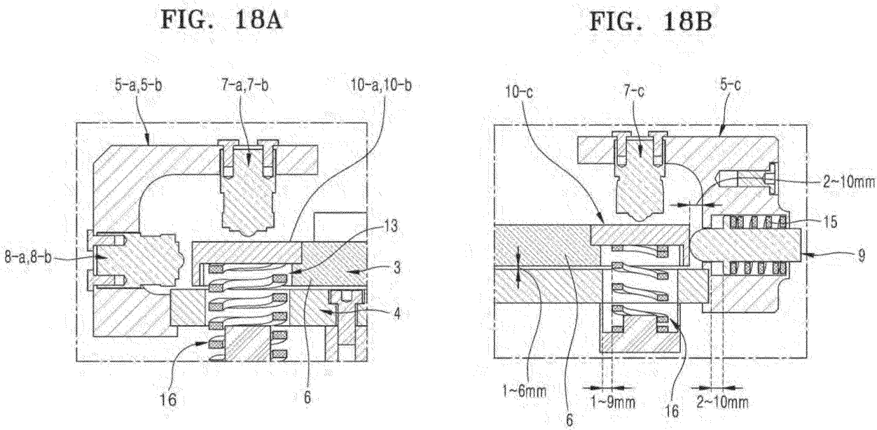

FIG. 19 shows an embodiment of the position control units 7-a, 7-b, 7-c, 8-a, and 8-b. A position control unit of the embodiment of FIG. 19 is a micro-screw jack, and may control horizontal movement or tilting of the moving plate 3 according to a moving position and its corresponding scale position of a moving body with respect to a fixed body.

In FIG. 19, the position control unit includes a fixed body and a moving body, and the moving body includes a plurality of adjusting holes. An adjustment lever such as a driver is inserted into an adjusting hole to rotate the moving body. The fixed body is fixed to a bracket. The moving body is rotatable about a central axis of the fixed body. A control measure for controlling rotational movement of the moving body is inserted into the fixing unit. For example, a set screw is inserted to control the rotational movement of the moving body and precisely control the movement of the moving plate. In an embodiment, the set screw rotates and moves the moving body by loosening the set screw using an adjustment lever when moving or tilting the moving plate. Conversely, when the moving plate is to be fixed at a set position, the moving body is fixed by tightening the set screw with the adjusting lever.

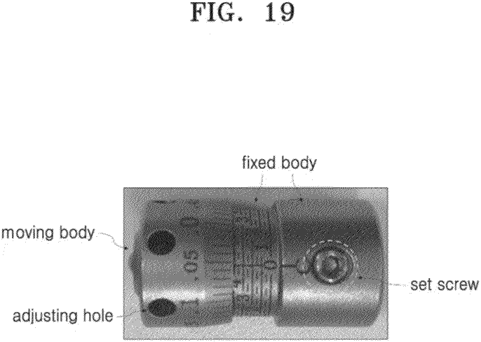

FIGS. 20A and 20B are views illustrating the principle of horizontal movement of the moving plate 3 according to an embodiment. In FIG. 20A, when each of the two horizontal movement position control units 8-a and 8-b moves in the forward direction (+), the corresponding control unit 8-a or 8-b pushes the plate 3 while advancing by a distance “a” in the forward direction (+), the alignment control unit 9 moves backward by a distance of “2a” in the reverse direction (-), and the moving plate 3 horizontally moves accordingly.

In FIG. 20B, opposite to FIG. 20A, the horizontal movement position control units 8-a and 8-b move backward by a distance of “a” in the reverse direction (-). At the same time, the alignment control unit 9 pushes the moving plate 3 while advancing by a distance of “2a” in the forward direction (+) by an elastic force, and the moving plate 3 moves horizontally in the opposite direction to FIG. 20A correspondingly. In FIG. 20A, both the horizontal position control units 8-a and 8-b move in the same direction by the same distance, but in another embodiment, by varying the moving direction and movement distance of each of the horizontal position control units 8-a and 8-b, there may be a technical effect that the moving direction and movement distance of the moving plate 3 may be more diversified and precisely controlled.

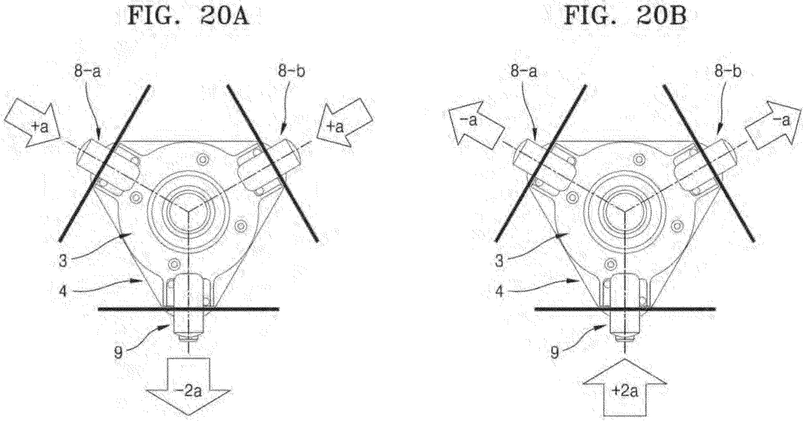

FIG. 21 is a view illustrating a horizontal moving direction of a moving plate and a heating block according to a movement distance and a moving direction of a horizontal movement position control unit of each substrate support unit in a substrate processing apparatus in which a plurality of reactors are installed. In each reactor of FIG. 21, an exhaust port is asymmetrically arranged in each reactor.

In FIG. 21, two horizontal movement position control units may be, for example, micro screw jacks and are denoted by #4 and #5, respectively. The alignment control unit may be an elastic body such as a spring. A moving direction of each moving plate is indicated by an arrow. In an embodiment according to FIG. 21, all of the moving plates may move horizontally in six directions ((1) to (6)).

Tables 1 and 2 show conditions for horizontally moving the moving plate 3 to each direction from (1) to (6) in each reactor in FIG. 21, that is, moving directions and movement distances of the horizontal position control unit of the moving plate 3 for horizontally moving the heating block.

Table 1

Conditions for lateral movement of moving plates in reactors RC1 and RC3

| Direction | Displacement control (mm) | | Remarks |
|---|---|---|---|
| Displacement unit: α (mm) | Micro-jack #4 | Micro-jack #5 | |
| (1) | (-)1.0 × α | (+)0.5 × α | Chamber center direction |
| (2) | (-)0.5 × α | (+)1.0 × α | |
| (3) | (+)0.5 × α | (+)0.5 × α | |
| (4) | (+)1.0 × α | (-)0.5 × α | Exhaust port direction |
| (5) | (+)0.5 × α | (-)1.0 × α | |
| (6) | (-)0.5 × α | (-)0.5 × α | |

Table 2

Conditions for lateral movement of moving plates in reactors RC2 and RC4

| Direction | Displacement control (mm) | | Remarks |
|---|---|---|---|
| Displacement unit: α (mm) | Micro-jack #4 | Micro-jack #5 | |
| (1) | (-)1.0 × α | (+)0.5 × α | Chamber center direction |
| (2) | (-)0.5 × α | (-)0.5 × α | |
| (3) | (+)0.5 × α | (-)1.0 × α | |
| (4) | (+)1.0 × α | (-)0.5 × α | Exhaust port direction |
| (5) | (+)0.5 × α | (+)0.5 × α | |
| (6) | (-)0.5 × α | (+)1.0 × α | |

In FIG. 21, Table 1 and Table 2, “α” is a displacement constant, which is a set value set depending on conditions and types of a substrate processing process. For example, α may be 0.2, 0.5, or 1.0, and may be appropriately selected according to process conditions and types.

For the first reactor RC1 and the third reactor RC3 in a symmetrical relationship therewith, when the moving plate is to be moved horizontally in a direction of the center of the chamber (direction 1), the horizontal movement position control unit #4 moves in the reverse direction (-) by 1.0 α mm and the other horizontal movement position control unit #5 moves in the forward direction (+) by 0.5 α mm.

In addition, for the first reactor RC1 and the third reactor RC3 in a symmetrical relationship therewith, when the moving plate is to be moved horizontally in a direction of an exhaust port of the reactor (direction 4), the horizontal movement position control unit #4 moves in the forward direction (+) by 1.0 α mm and the other horizontal movement position control unit #5 moves in the reverse direction (-) by 0.5 α mm.

The movement of the moving plate may be equally applied to the second reactor RC2 and the fourth reactor RC4, and thus a detailed description thereof will be omitted.

In a multi-reactor chamber as shown in FIG. 21, there is a problem in that the symmetry between a heating block and a chamber structure surrounding the heating block decreases and the asymmetry increases due to thermal expansion of the chamber at a high temperature.

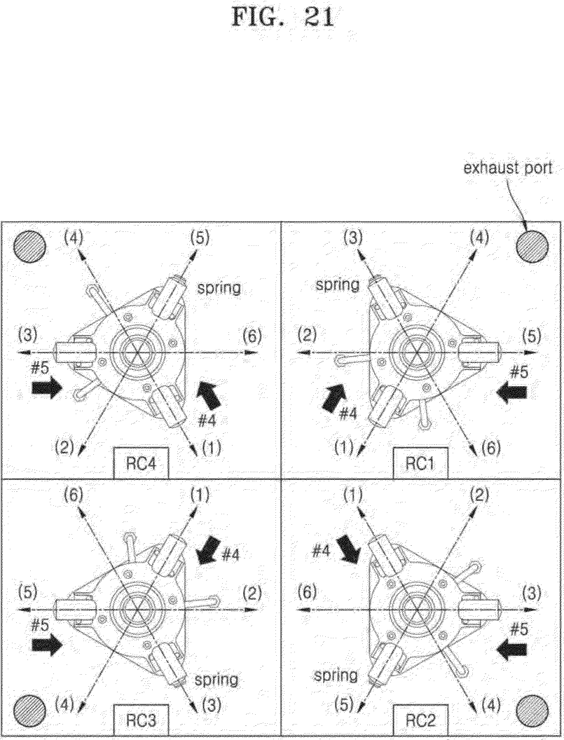

FIG. 22 shows one such case. In FIG. 22, the symmetry of arrangement between the heating block 154 and a chamber structure surrounding the heating block 154 is lowered due to thermal deformation at a high temperature in a multi-reactor chamber. For example, as shown in FIG. 22, gaps between the heating block 154 and the gas flow control ring 158 surrounding the heating block 154 are not constant (G≠G′). Non-uniform spacing causes a non-uniform exhaust flow around a substrate and lowers the uniformity of a thin film on the substrate. Accordingly, a horizontal movement device and method of a substrate support unit according to the disclosure may have a technical effect to maintain the symmetry of arrangement between the heating block 154 and the chamber structure even at a high temperature.

The technical idea of the disclosure also provides a tilting function for tilting the substrate support unit. FIG. 22 shows that thermal deformation occurs in a horizontal direction in a reactor during a high-temperature process. However, in addition to a temperature condition, a top lid 1512 of a chamber is also sagged and deformed downward by a vacuum force applied to an inner space of the chamber. In particular, such a phenomenon is conspicuous at the center of the top lid 1512. Therefore, the gas supply units 151 and 153 installed on the top lid 1512 are also tilted toward the center of the top lid 1512 together. Spacing between a substrate support unit that is a heating block 154 and the gas supply unit 151 or 153, that is, the width of the reaction space 1511, e.g. the distance between the lower surface of the gas supply unit 151 or 153 and the upper surface of the heating block 154 also becomes non-uniform over a reaction space. Accordingly, the technical idea of the disclosure provides that when a top lid and a gas supply unit mounted on the top lid are tilted, a substrate support unit is also tilted together correspondingly to maintain a uniform reaction space.

FIGS. 16A-16C, 18A and 18B show the vertical position control units 7-a, 7-b, and 7-c capable of tilting the moving plate 3. A vertical position control unit may be a micro screw jack as shown in FIG. 19. Each of the three vertical position control units may move a different distance in the forward direction (+) to push at least one of the position control unit support units 10-a, 10-b, and 10-c downward to tilt the moving plate 3 in a specific direction. Alternatively, each of the three vertical position control units may move in the reverse direction (-) to push at least one of the position control unit support units 10-a, 10-b, and 10-c upward to tilt the moving plate 3 in a specific direction. The driving method is the same as the above-mentioned horizontal position control units 8-a and 8-b, and thus the overlapping description will not be given herein.

FIG. 23 is a view illustrating an embodiment of tilting the moving plate 3. In this embodiment, a reactor is simplified for easy understanding, and the actual structure corresponds to FIGS. 15 to 22.

In FIG. 23, when a vertical position control unit 7 moves vertically by a distance b in the forward direction (+), the heating block 1 moves horizontally by a distance g × b while being tilted by an angle α. Where g is a geometric constant expressed as a ratio of R2/R1, and is a value that compensates for an effect of the rotation angle α on the displacement when the heating block 1 moves horizontally.

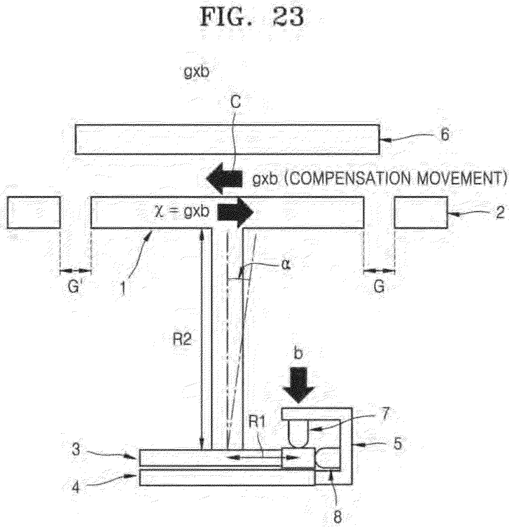

On the other hand, when the heating block 1 moves horizontally while tilting, gaps between the heating block 1 and a gas flow control ring 2 becomes non-uniform (G≠G′). Accordingly, after the heating block 1 is tilted, in order to make the gap between the heating block 1 and the gas flow control ring 2 uniform, compensation movement of the moving plate 3 and the heating block 1 needs to be additionally performed. As shown in FIG. 23, the heating block 1 moves horizontally by the distance g × b in the opposite direction by the moved distance (see C of FIG. 23). This compensation movement proceeds by adjusting the horizontal position control units 8 of the moving plate 3 as shown in FIG. 24.

In FIG. 24, when each of the horizontal position control units 8-a and 8-b is moved in the reverse direction (-), the alignment control unit 9 pushes the moving plate in the forward direction (+) and the heating block makes compensation movement in the opposite direction to the horizontal moving direction caused by a tilted state. In FIG. 24, a reverse movement distance of the horizontal position control units 8-a and 8-b is calculated by reflecting a geometric constant g according to the tilting of the heating block. For example, in FIG. 24, the moving direction of the moving plate is compensated for in the direction (6) of RC1 and RC3 according to FIG. 21 and Table 1 described above.

In the embodiment of FIGS. 23 to 24, moving of the moving plate is compensated for by moving the alignment control unit 9 in the forward direction, but in another embodiment, the moving plate is compensated for moving while moving at least one of the two horizontal position control units 8-a and 8-b and the alignment control unit 9 in the forward or reverse direction according to a direction in which the heating block is tilted.

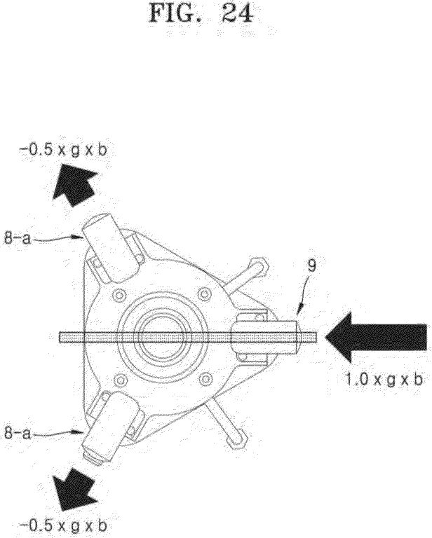

FIG. 25 and Table 3 show a movement distance of each of the horizontal position control units (micro jacks #4 and #5) for compensating for moving a heating block in a horizontal direction when the heating block is tilted by moving each of the vertical position control units (micro jacks #1, #2, and #3) by a certain distance. A moving direction of each position control unit may be a forward (+) or a reverse (-) direction. For example, Table 3 shows distances that the horizontal position control units move for horizontal compensation movement of the heating block when the vertical position control units are moved by b1, b2, and b3, respectively. The movement distance of the horizontal position control units is calculated by reflecting the geometric constant g.

Table 3

Movement distance of each position control unit of a moving plate for tilting and lateral compensation movement of heating block

| Micro-Jack | Function | Movement distance for tilting | Movement distance for lateral compensation movement |
|---|---|---|---|
| #1 | Leveling | b1 | - |
| #2 | (Tilting) | b2 | - |
| #3 | | b3 | - |
| #4 | Compensating lateral movement | - | 1 xgxb1 -0.5xgxb2-0.5xgxb3 |
| #5 | | - | -0.5xgxb1 -0.5xgxb2+1xgxb3 |

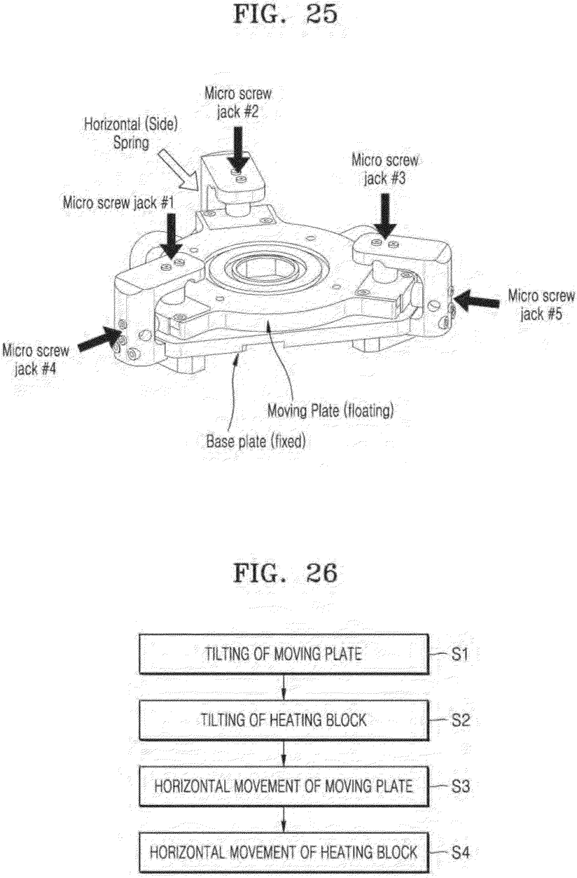

FIG. 26 is a flowchart illustrating a process of tilting and horizontal compensation movement of the heating block according to FIG. 25 and Table 3.

Referring to FIG. 26, in operation S1, in order to correct deformation/misalignment of a substrate processing apparatus occurred under a high temperature and/or vacuum environment, tilting of a moving plate is performed using a vertical position control unit. In operation S2, by tilting the moving plate, a heating block connected to the moving plate is tilted. Thereafter, in operation S3, in order to compensate for horizontal movement of the heating block caused by tilting, horizontal movement of the moving plate is performed using a horizontal position control unit. In operation S4, the heating block connected to the moving plate is moved in the horizontal direction by the horizontal movement of the moving plate.

According to the disclosure, a substrate support unit may facilitate horizontal movement and tilt of the heating block as a chamber is deformed by thermal expansion and vacuum force at high temperatures. In addition, by maintaining the symmetry of arrangement between a heating block and surrounding components, it may contribute to the improvement of reproducibility and productivity of a substrate processing process. Furthermore, by stopping the operation of a substrate processing apparatus, lowering the temperature, and performing maintenance work, the existing maintenance process that reduces the uptime and the operation efficiency of the apparatus may be omitted, thereby contributing to the improvement of operation efficiency and productivity of the substrate processing apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a first plate;
a second plate on the first plate;
a position control unit configured to change a relative position of the second plate with respect to the first plate; and
a support unit configured to permit movement of the second plate while supporting the second plate.

2. The substrate processing apparatus of claim 1, wherein the support unit is configured to prevent an over-constraint state of the second plate by the position control unit.

3. The substrate processing apparatus of claim 1, wherein the support unit comprises an elastic member configured to generate an elastic force that changes according to the movement of the second plate.

4. The substrate processing apparatus of claim 1, further comprising:
a substrate mounting unit connected to the second plate; and
a driving unit connected to the first plate,
wherein a first moving range of the substrate mounting unit moved by the driving unit is greater than a second moving range of the substrate mounting unit moved by the position control unit.

5. The substrate processing apparatus of claim 1, wherein the position control unit comprises a vertical position control unit configured to vertically move the second plate with respect to the first plate.

6. The substrate processing apparatus of claim 5, further comprising:
a bracket connected to the first plate,
wherein the vertical position control unit is fixed to the bracket and configured to apply a force toward an upper surface of the second plate.

7. The substrate processing apparatus of claim 5, wherein the support unit is below the vertical position control unit.

8. The substrate processing apparatus of claim 7, further comprising:
a lower cover connected to the first plate,
wherein the support unit extends from the lower cover toward the second plate through a through hole of the first plate, and
a side surface of the support unit is apart from a side surface of the through hole.

9. The substrate processing apparatus of claim 8, wherein
the support unit extends through at least a portion of the second plate, and
the side surface of the support unit is apart from a side surface of the second plate.

10. The substrate processing apparatus of claim 5, further comprising:
a substrate mounting unit connected to the second plate, and
the position control unit further comprises a horizontal position control unit configured to horizontally move the second plate with respect to the first plate,
wherein the horizontal position control unit is configured to perform a compensating operation for horizontal movement of the substrate mounting unit caused by tilting of the second plate by the movement of the vertical position control unit.

11. The substrate processing apparatus of claim 10, wherein
a length from a center of the second plate to a contact point between the second plate and the vertical position control unit is a first length,
a length from the second plate to the substrate mounting unit is a second length, and
the vertical position control unit moves by a third length at the contact point,
wherein the horizontal position control unit is configured to move the second plate by a value obtained by multiplying the second length by the third length and dividing the first length.

12. The substrate processing apparatus of claim 1, wherein the position control unit comprises a horizontal position control unit configured to horizontally move the second plate with respect to the first plate.

13. The substrate processing apparatus of claim 12, wherein the support unit is arranged on a side surface of the second plate.

14. The substrate processing apparatus of claim 13, further comprising:
a first bracket connected to the first plate,
wherein the horizontal position control unit is fixed to the first bracket and configured to apply a force toward a side surface of the second plate.

15. The substrate processing apparatus of claim 14, wherein the support unit comprises an elastic member and an elastic force transmission unit connected to the elastic member,
wherein the elastic force transmission unit is configured to apply an elastic force generated by the elastic member to the side surface of the second plate.

16. The substrate processing apparatus of claim 15, further comprising:
a second bracket connected to the first plate,
wherein the elastic member and the elastic force transmission unit are inserted into an accommodating portion of the second bracket, and
the elastic force transmission unit protrudes from a side surface of the second bracket through the accommodating portion of the second bracket and contacts the side surface of the second plate.

17. The substrate processing apparatus of claim 16, wherein
the elastic force transmission unit has a round end, and
the end of the elastic force transmission unit and an end of the horizontal position control unit are configured to contact side surfaces of the second plate at the same level.

18. The substrate processing apparatus of claim 16, wherein the elastic force transmission unit comprises:
a body portion inserted into the elastic member;
a round portion connected to the body portion; and
an extension protruding from the body portion,
wherein the extension is in contact with the elastic member.

19. The substrate processing apparatus of claim 12, wherein
the horizontal position control unit comprises two position control units arranged on a side surface of the second plate,
wherein the two position control units and the support unit are symmetrically arranged with respect to a center of the second plate, and
as the two position control units move toward a center of the first plate by a first distance, the second plate moves toward the support unit by a second distance,
wherein the second distance is twice the first distance.

20. The substrate processing apparatus of claim 1, wherein
the second plate comprises a first protrusion, a second protrusion, and a third protrusion,
the position control unit comprises:
a first position control unit on the first protrusion;
a second position control unit on the second protrusion;
a third position control unit on the third protrusion;
a fourth position control unit next to the first protrusion; and
a fifth position control unit next to the second protrusion, and
the support unit comprises:
a first support unit next to the third protrusion;
a second support unit below the first position control unit;
a third support unit below the second position control unit; and
a fourth support unit below the third position control unit.

21. A substrate processing apparatus comprising:
a first plate including a first bracket, a second bracket, and a third bracket;
a second plate arranged on the first plate and including a first protrusion, a second protrusion, and a third protrusion;
a first position control unit arranged between the first bracket and an upper surface of the first protrusion;
a second position control unit arranged between the second bracket and an upper surface of the second protrusion;
a third position control unit arranged between the third bracket and an upper surface of the third protrusion;
a fourth position control unit arranged between the first bracket and a side surface of the first protrusion;
a fifth position control unit between the second bracket and a side surface of the second protrusion;
a first support unit between the third bracket and a side surface of the third protrusion;
a second support unit below the first position control unit;
a third support unit below the second position control unit; and
a fourth support unit below the third position control unit.

22. A substrate processing apparatus comprising:
a first plate; and
a second plate on the first plate;
a position control unit configured to move the second plate with respect to the first plate; and
a support unit configured to provide an elastic force to receive the movement of the second plate by the position control unit.
